(19) United States
(12) Patent Application Publication
(10) Pub. No.: US 2012/0068123 A1
(43) Pub. Date: Mar. 22, 2012

(54) USE OF PHTHALOCYANINE COMPOUNDS WITH ARYL OR HETARYL SUBSTITUENTS IN ORGANIC SOLAR CELLS

(75) Inventors: Sudhakar Sundarraj, Singapore (SG); Ingmar Bruder, Harthausen (DE); Jae Hyung Hwang, Mannheim (DE); Jan Schoeneboom, Mannheim (DE); Martin Koenemann, Mannheim (DE); Sheeja Bahulayan, Singapore (SG); Antti Ojala, Ludwigshafen (DE); Augustine Leow Yoon Wui, Singapore (SG); Peter Erk, Frankenthal (DE); Ruediger Sens, Ludwigshafen (DE); Thomas Gessner, Heidelberg (DE)

(73) Assignee: BASF SE, Ludwigshafen (DE)

(21) Appl. No.: 13/322,210

(22) PCT Filed: May 25, 2010
(86) PCT No.: PCT/EP2010/057099

§ 371 Date: Nov. 23, 2011

(30) Foreign Application Priority Data
May 26, 2009 (EP) 09161134.3

(51) Int. Cl. H01B 1/12; C07D 487/22; H01B 1/04; C07F 3/06

(52) U.S. Cl. 252/506; 540/140; 540/123; 252/500; 540/122; 252/519.2; 252/510

(57) ABSTRACT

The present invention relates to organic solar cell comprising at least one photoactive region comprising an organic donor material in contact with an organic acceptor material and forming a donor-acceptor heterojunction, wherein the photoactive region comprises at least one compound of the formulae Ia and/or Ib where M, (R^{a})ₘ and (R^{b})ₙ as described in the claims and description. Furthermore, the present invention relates to compounds of formulae Ia and Ib, wherein M, (R^{a})ₘ and n are as described in the claims and description and R^{b} is fluorine and to a process for preparing them.

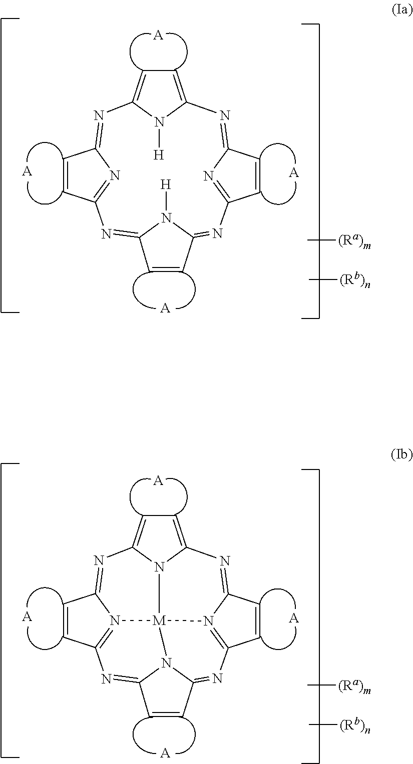

### BACKGROUND OF THE INVENTION

The present invention relates to the use of phthalocyanine compounds and arene-anellated phthalocyanine compounds with aryl or hetaryl substituents in an organic solar cell, comprising at least one electron-conducting organic layer in contact with at least one hole-conducting organic layer and forming a photoactive heterojunction.

### DESCRIPTION OF THE RELATED ART

Phthalocyanines and their derivatives have been the subject of intensive studies for many years due to their properties as dye stuffs, paints and colors. Over the past two decades, phthalocyanines and their derivatives have also attracted increasing attention owing to the excellent electrical and optical properties. As a result, they have found increasing use in different applications, such as photovoltaics, electrochromism, optical data storage, laser dyes, liquid crystals, chemical sensors, electrophotography and photosensitizers for photodynamic therapy.

Owing to diminishing fossil raw materials and the CO₂ which is formed in the combustion of these raw materials acting as a greenhouse gas, direct energy generation from sunlight is playing an increasing role. “Photovoltaics” is understood to mean the direct conversion of radiative energy, principally solar energy, to electrical energy.

In contrast to inorganic solar cells, the light does not directly generate free charge carriers in organic solar cells, but rather excitons are formed first, i.e. electrically neutral excited states in the form of electron-hole pairs. These excitons can be separated only by very high electrical fields or at suitable interfaces. In organic solar cells, sufficiently high fields are unavailable, and so all existing concepts for organic solar cells are based on exciton separation at photoactive interfaces (organic donor-acceptor interfaces, heterojunctions). For this purpose, it is necessary that excitons which have been generated in the volume of the organic material can diffuse to this photoactive interface. The diffusion of excitons to the active interface thus plays a critical role in organic solar cells. In order to make a contribution to the photocurrent, the exciton diffusion length in a good organic solar cell must at least be in the order of magnitude of the typical penetration depth of light, in order that the predominant portion of the light can be utilized. The efficiency of a solar cell depends upon its open-circuit voltage (V_{OC}). It indicates the maximum voltage of the irradiated cell with an open circuit. Further important parameters are the short-circuit current density (J_{SC}), the fill factor (FF) and the efficiency (η).

The first efficient organic solar cell containing phthalocyanines was reported by Tang in 1986 (C. W. Tang et al., Appl. Phys. Lett. 48, 183 (1986)). It consisted of a two-layer system composed of a copper phthalocyanine (CuPc) as a p-conductor and perylene-3,4:9,10-tetracarboxylic acid bisbenzimidazole (PTCBI) as an n-conductor and exhibited an efficiency of 1%.

There has been no lack of attempts to improve the efficiency of organic solar cells. Some approaches to the achievement or improvement of the properties of organic solar cells are listed below:
The use of an exciton blocking layer, e.g. made of bathocuproine.
One of the contact metals used has a large work function and the other a small work function, such that a Schottky barrier is formed by the organic layer.
Various dopants serve, inter alia, to improve the transport properties.
Arrangement of a plurality of individual solar cells so as to form a so-called tandem cell which can be improved further, for example, by using p-i-n structures with doped transport layers of large band gap.

Instead of increasing the exciton diffusion length, it is alternatively also possible to reduce the mean distance to the next interface. To this end, it is possible to use mixed layers composed of donors and acceptors which form an interpenetrating network in which internal donor-acceptor heterojunctions are possible. S. Ushida et al. describe in Appl. Phys. Lett., Vol. 84, no. 21, p. 4218-4220, an organic solar cell with a vacuum codeposited donor-acceptor copper phthalocyanine (CuPc)/C₆₀ mixed layer forming a donor-acceptor-bulk heterojunction (BHJ). A power efficiency η_{P} of 3.5 at 1 sun was obtained.

The use of unsubstituted phthalocyanines with different central metals like Cu, Zn, Al, Ti and Sn in organic solar cells with donor-acceptor-heterojunctions is generally known.

The afore-mentioned phthalocyanines employed in organic solar cells of the prior art are characterized by a flat molecular structure and show aggregation. Due to this aggregation the flat phthalocyanines usually have good charge transporting properties with a modest solid state absorption. Until now, it was thought that the charge transporting properties of phthalocyanines wherein the macrocyclic structure is not planar (e.g. due to steric complex substituents) are insufficient for solar cells with donor-acceptor-heterojunctions.

Phthalocyanines and phthalocyanine derivatives, e.g. core extended phthalocyanines, with side groups like aryl, hetaryl, aryloxy or thioaryloxy are known. Their synthesis can be performed by methods described in the literature.

WO 2007/104685 describes the use of aryloxy, cycloalkyloxy or alkyloxy substituted phthalocyanines as marking substances for liquids.

JP 3857327 B2 describes the synthesis of aryloxy substituted phthalocyanine compounds with high solubility in organic solvents. They are useful inter alia for organic semiconductor devices.

A-Z. Liu and S-B. Lei describe in Surf. Interface Anal. 39, (2007), 33-38 the structural dependent packing behavior of aryl and aryloxy substituted phthalocyanines on the surface of granite.

T. Sugimori et al. describe in Chemistry Letters (2000), 1200-1201 the synthesis of phthalocyanines peripherally substituted with four phenyl derivatives from the corresponding phthalonitriles. The phthalonitriles are obtained by Suzuki-Miyaura coupling.

N. Kobayashi et al. describe in J. Am. Chem. Soc. 123, (2001), 10740-10741 the synthesis and structural characterization of octaphenyl substituted phthalocyanines and anthracenocyanines. The structure shows a large deviation from planarity due to the steric congestion of the protruding phenyl groups.

JP 2008-214228 A describes phenoxy substituted phthalocyanine with discotic liquid crystal phase and various potential uses thereof, inter alia in solar cells. A use in organic solar cells with a donor-acceptor heterojunction is not disclosed.

JP 3860616 B2 describes phthalocyanine compounds which are bound to a nitrogen containing heterocyclic ring via a carbon atom of the phthalocyanine ring and a nitrogen atom of the heterocyclic ring. Also mentioned in very general terms is the use of such compounds as dyes in photoelectric conversion devices.

T. Muto et al. describe in Chem. Commun., 2000, 1649-1650 phthalocyanine derivatives with 2-thienyl substituents. Also in this document a use in organic solar cells is not disclosed.

It is also known to employ phthalocyanines and phthalocyanine derivatives as sensitizers in Grätzel solar cells (dye-sensitized solar cells, DSCs). In dye-sensitized solar cells the photoactive material comprises an inorganic semiconductor material (e.g. TiO₂) with an absorbed organic dye. In these types of solar cells charge transport properties of dyes do not play any role since this role is taken by the inorganic semiconductor.

Y. Amao and T. Komori describe in Langmuir 2003, 19, 8872-8875 dye-sensitized solar cells using a TiO₂ nanocrystalline film electrode modified by an aluminium phthalocyanine with phenoxy groups.

D. Wrobel and A. Boguta describe in J. Photochem. Photobio. A: Chem. 150 (2002) 67-76 dye-sensitized solar cells containing ZnPc dyes.

The preparation of organic solar cells with a photoactive region composed of a donor-acceptor heterojunction is described inter alia in WO 2004/083958 A2 and WO 2006/092134 A1. Organic photovoltaic cells with a mixed (or bulk) heterojunction are described by J. Xue, B. P. Rand, S. Uchida and S. R. Forrest in J. Appl. Phys. 98, 124903 (2005).

H. Ding et al. describe in J. Mater. Sci. 36, (2001), 5423-5428 the observation of a photoelectric effect in a photoelectrochemical cell comprising a mixed film of 060 and tri-(2,4-di-tert.-amylphenoxy)-(8-quinolinolyl) copper phthalocyanine.

It has now been found that, surprisingly, phthalocyanine compounds and arene-anellated phthalocyanine compounds having aryl and/or hetaryl substituents, wherein those substituents are bound to the fused arene ring of the pyrrol moiety by a single bond or are linked via oxygen, sulphur or nitrogen to the fused arene ring of the pyrrol moiety, are particularly advantageously suitable for the use in the photovoltaic layer of organic solar cells having donor-acceptor heterojunctions. They are suitable especially as charge transport materials and/or absorber materials.

### SUMMARY OF THE INVENTION

In a first aspect, the invention provides an organic solar cell comprising at least one photoactive region comprising an organic donor material in contact with an organic acceptor material and forming a donor-acceptor heterojunction, wherein the photoactive region comprises at least one compound of the formulae Ia and/or Ib

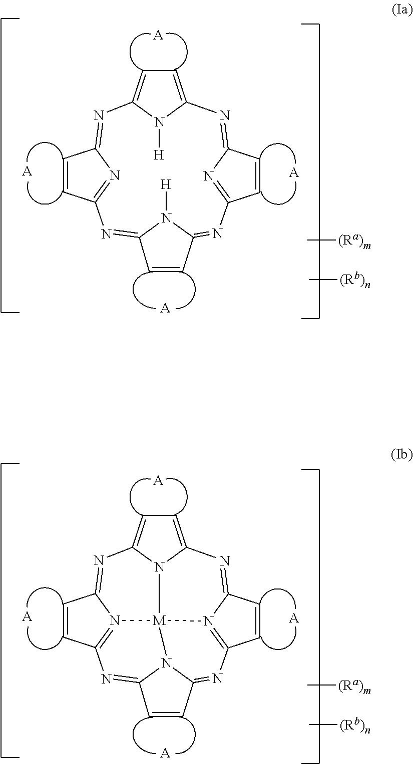

where
M in formula Ib is a divalent metal, a divalent metal atom containing group or a divalent metalloid group;
A at each occurrence, is independently of each other a fused arene ring selected from the group consisting of a benzene ring, naphthalene ring, anthracene ring and phenanthrene ring;
R^{a} at each occurrence, is independently selected from aryl, aryloxy, arylthio, monoarylamino, diarylamino, hetaryl, hetaryloxy, oligo(het)aryl and oligo(het)aryloxy, wherein each aryl, aryloxy, arylthio, monoarylamino, diarylamino, hetaryl, hetaryloxy, oligo(het)aryl and oligo(het)aryloxy may be unsubstituted or carries at least one substituents R^{aa} independently selected from cyano, hydroxyl, nitro, carboxyl, halogen, alkyl, cycloalkyl, haloalkyl, halocycloalkyl, alkoxy, haloalkoxy, alkylsulfanyl, haloalkylsulfanyl, amino, monoalkylamino, dialkylamino, NH(aryl) and N(aryl)₂;
R^{b} at each occurrence, is independently selected from cyano, hydroxyl, nitro, carboxyl, carboxylate, SO₃H, sulfonate, halogen, alkyl, haloalkyl, cycloalkyl, halocycloalkyl, alkoxy, haloalkoxy, alkylsulfanyl, haloalkylsulfanyl, amino, monoalkylamino and dialkylamino;
m is 1, 2, 3, 4, 5, 6, 7, 8, 9, 10, 11, 12, 13, 14, 15 or 16; and
n is 0, 1, 2, 3, 4, 5, 6, 7, 8, 9, 10, 11, 12, 13, 14, 15, 16, 17, 18, 19, 20, 21, 22 or 23.

According to a special embodiment, the organic solar cell comprises at least one compound of the formula Ia and/or Ib, that bears at least one sulfur containing hetaryl substituent. Preferred sulfur containing hetaryl substituents are selected from 2-thienyl, 3-thienyl, thiazol-2-yl, thiazol-5-yl, [1,3,4]thiadiazol-2-yl, benzo[b]thiophen-2-yl and mixtures thereof. Especially preferred is 2-thienyl. According to this special embodiment, the organic solar cell solar comprises at least one photoactive region that forms a bulk heterojunction (BHJ).

According to a special embodiment of the organic solar cell, at least one compound of the formulae Ia and/or Ib is used in combination with at least one further different semiconductor material that comprises at least one fullerene and/or fullerene derivative.

According to a special embodiment, the organic solar cell is in the form of a single cell, in the form of a tandem cell or in the form of a multijunction solar cell.

In a further aspect, the invention provides a compound of the formulae Ia-F or Ib-F,

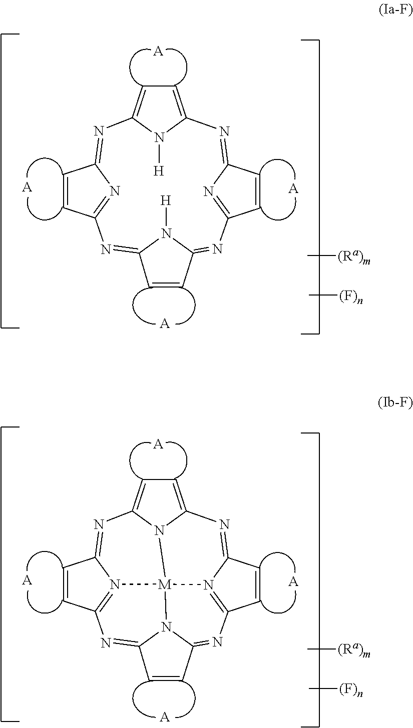

wherein
M in formula Ib-F is a divalent metal, a divalent metal atom containing group or a divalent metalloid group;
A at each occurrence, is a fused arene ring selected from a benzene ring, naphthalene ring, anthracene ring and phenanthrene ring;
R^{a} at each occurrence, is independently selected from aryl, aryloxy, arylthio, monoarylamino, diarylamino, hetaryl, hetaryloxy, oligo(het)aryl or oligo(het)aryloxy, wherein each aryl, aryloxy, arylthio, monoarylamino, diarylamino, hetaryl, hetaryloxy, oligo(het)aryl or oligo(het)aryloxy may be unsubstituted or carries at least one substituents R^{aa} independently selected from cyano, hydroxyl, nitro, carboxyl, halogen, alkyl, cycloalkyl, haloalkyl, halocycloalkyl, alkoxy, haloalkoxy, alkylsulfanyl, haloalkylsulfanyl, amino, monoalkylamino, dialkylamino, NH(aryl) and N(aryl)₂;
m is 1, 2, 3, 4, 5, 6, 7, 8, 9, 10, 11, 12, 13, 14 or 15; and
n is 1, 2, 3, 4, 5, 6, 7, 8, 9, 10, 11, 12, 13, 14, 15, 16, 17, 18, 19, 20, 21, 22 or 23.

In a further aspect of the present invention, the invention provides a process for preparing compounds of the formula Ib-F

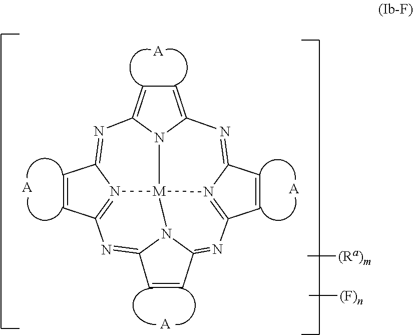

wherein
M is a divalent metal, a divalent metal atom containing group or a divalent metalloid group;
A at each occurrence, is a fused arene ring selected from a benzene ring, naphthalene ring, anthracene ring and phenanthrene ring;
R^{a} at each occurrence, is independently selected from aryl, aryloxy, arylthio, monoarylamino, diarylamino, hetaryl, hetaryloxy, oligo(het)aryl or oligo(het)aryloxy, wherein each aryl, aryloxy, arylthio, monoarylamino, diarylamino, hetaryl, hetaryloxy, oligo(het)aryl or oligo(het)aryloxy may be unsubstituted or carries at least one substituents R^{aa} independently selected from cyano, hydroxyl, nitro, carboxyl, halogen, alkyl, cycloalkyl, haloalkyl, halocycloalkyl, alkoxy, haloalkoxy, alkylsulfanyl, haloalkylsulfanyl, amino, monoalkylamino, dialkylamino, NH(aryl) and N(aryl)₂;
m is 1, 2, 3, 4, 5, 6, 7, 8, 9, 10, 11, 12, 13, 14 or 15, and
n is 1, 2, 3, 4, 5, 6, 7, 8, 9, 10, 11, 12, 13, 14, 15, 16, 17, 18, 19, 20, 21, 22 or 23,
   comprising
a) providing an educt composition which comprises at least one compound selected from compounds of the formulae IIa, IIb, IIc and IId

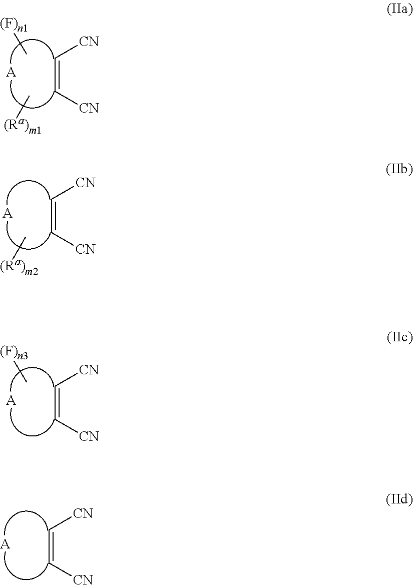

wherein
the groups A are, independently of each other, a fused arene ring selected from a benzene ring, naphthalene ring, anthracene ring and phenanthrene ring;
m₁ is 1, 2, 3 or 4;
m₂ is 1, 2, 3 or 4;
n₁ is 1, 2, 3, 4, 5, 6 or 7;
n₃ is 0, 1, 2, 3, 4, 5, 6, 7 or 8;
with the proviso that the sum of all indices m₁ plus the sum of all indices m₂ is not more than 15,
with the proviso that the sum of all indices n₁ plus the sum of all indices n₂ is not more than 23,
with the proviso that the educt composition comprises at least one compound of the formula IIa or that the educt composition comprises at least one compound of the formula IIb and at least one compound of the formula IIc,
b) reacting the educt composition at an elevated temperature with a compound of a metal M.

### DESCRIPTION OF THE INVENTION

The expression “halogen” denotes in each case fluorine, bromine, chlorine or iodine, particularly chlorine or fluorine.

In the context of the present invention, the expression “alkyl” comprises straight-chain or branched alkyl groups. Alkyl is preferably C₁-C₃₀-alkyl, more preferably C₁-C₂₀-alkyl and most preferably C₁-C₁₂-alkyl. Examples of alkyl groups are especially methyl, ethyl, n-propyl, isopropyl, n-butyl, isobutyl, sec-butyl, tert-butyl, n-pentyl, neo-pentyl, n-hexyl, n-heptyl, n-octyl, n-nonyl, n-decyl, n-undecyl, n-dodecyl, n-tridecyl, n-tetradecyl, n-hexadecyl, n-octadecyl and n-eicosyl.

The expression alkyl also comprises alkyl radicals whose carbon chains may be interrupted by one or more nonadjacent groups which are selected from —O—, —S—, —NR^{e}—, —C(═O)—, —S(═O)— and/or —S(═O)₂—. R^{e} is preferably hydrogen, alkyl, cycloalkyl, heterocycloalkyl, aryl or hetaryl.

The above remarks regarding alkyl also apply to the alkyl moiety in alkoxy and alkylsulfanyl (=alkylthio).

In the context of the present invention, the term “haloalkyl” comprises straight-chained or branched alkyl groups, wherein some or all of the hydrogen atoms in these groups are replaced by halogen atoms. Suitable and preferred alkyl groups are the aforementioned. The halogen atoms are preferably selected from fluorine, chlorine and bromine, more preferably from fluorine and chlorine. Examples of haloalkyl groups are especially chloromethyl, bromomethyl, dichloromethyl, trichloromethyl, fluoromethyl, difluoromethyl, trifluoromethyl, chlorofluoromethyl, dichlorofluoromethyl, chlorodifluoromethyl, 1-chloroethyl, 1-bromoethyl, 1-fluoroethyl, 2-fluoroethyl, 2,2-difluoroethyl, 2,2,2-trifluoroethyl, 2-chloro-2-fluoroethyl, 2-chloro-2,2-difluoroethyl, 2,2-dichloro-2-fluoroethyl, 2,2,2-trichloroethyl and pentafluoroethyl, 2-fluoropropyl, 3-fluoropropyl, 2,2-difluoropropyl, 2,3-difluoropropyl, 2-chloropropyl, 3-chloropropyl, 2,3-dichloropropyl, 2-bromopropyl, 3-bromopropyl, 3,3,3-trifluoropropyl, 3,3,3-trichloropropyl, CH₂—C₂F₅, CF₂—C₂F₅, CF(CF₃)₂, 1-(fluoromethyl)-2-fluoroethyl, 1-(chloromethyl)-2-chloroethyl, 1-(bromomethyl)-2-bromoethyl, 4-fluorobutyl, 4-chlorobutyl, 4-bromobutyl, nonafluorobutyl, 5-fluoro-1-pentyl, 5-chloro-1-pentyl, 5-bromo-1-pentyl, 5-iodo-1-pentyl, 5,5,5-trichloro-1-pentyl, undecafluoropentyl, 6-fluoro-1-hexyl, 6-chloro-1-hexyl, 6-bromo-1-hexyl, 6-iodo-1-hexyl, 6,6,6-trichloro-1-hexyl or dodecafluorohexyl.

The above remarks regarding haloalkyl also apply to the haloalkyl moiety in haloalkoxy and haloalkylsulfanyl (also referred to as haloalkylthio).

In the context of the present invention, the term “cycloalkyl” denotes a cycloaliphatic radical having usually from 3 to 10, preferably 5 to 8, carbon atoms such as cyclopropyl, cyclobutyl, cyclopentyl, cyclohexyl, cycloheptyl, cyclooctyl, norbornyl, bicyclo[2.2.2]octyl or adamantyl.

In the context of the present invention, the term “halocycloalkyl” comprises cycloalkyl groups as mentioned above, wherein some or all of the hydrogen atoms in these groups may be replaced by halogen atoms as mentioned above.

In the context of the present invention, the term “aryl” refers to mono- or polycyclic aromatic hydrocarbon radicals. Aryl usually is an aromatic radical having 6 to 24 carbon atoms, preferably 6 to 20 carbon atoms, especially 6 to 14 carbon atoms as ring members. Aryl is preferably phenyl, naphthyl, indenyl, fluorenyl, anthracenyl, phenanthrenyl, naphthacenyl, chrysenyl, pyrenyl, coronenyl, perylenyl, etc., and more preferably phenyl or naphthyl.

Substituted aryls may, depending on the number and size of their ring systems, have one or more (e.g. 1, 2, 3, 4, 5 or more than 5) substituents independently selected from the substituents R^{aa} as defined above.

Aryl which bears one or more substituents R^{aa} is, for example, 2-, 3- and 4-methylphenyl, 2,4-, 2,5-, 3,5- and 2,6-dimethylphenyl, 2,4,6-trimethylphenyl, 2-, 3- and 4-ethyl-phenyl, 2,4-, 2,5-, 3,5- and 2,6-diethylphenyl, 2,4,6-triethylphenyl, 2-, 3- and 4-propyl-phenyl, 2,4-, 2,5-, 3,5- and 2,6-dipropylphenyl, 2,4,6-tripropylphenyl, 2-, 3- and 4-isopropylphenyl, 2,4-, 2,5-, 3,5- and 2,6-diisopropylphenyl, 2,4,6-triisopropylphenyl, 2-, 3- and 4-butylphenyl, 2,4-, 2,5-, 3,5- and 2,6-dibutylphenyl, 2,4,6-tributylphenyl, 2-, 3- and 4-isobutylphenyl, 2,4-, 2,5-, 3,5- and 2,6-diisobutylphenyl, 2,4,6-triisobutylphenyl, 2-, 3- and 4-sec-butylphenyl, 2,4-, 2,5-, 3,5- and 2,6-di-sec-butylphenyl, 2,4,6-tri-sec-butylphenyl, 2-, 3- and 4-tert-butylphenyl, 2,4-, 2,5-, 3,5- and 2,6-di-tert-butylphenyl and 2,4,6-tri-tert-butylphenyl; 2-, 3- and 4-methoxyphenyl, 2,4-, 2,5-, 3,5- and 2,6-dimethoxyphenyl, 2,4,6-trimethoxyphenyl, 2-, 3- and 4-ethoxyphenyl, 2,4-, 2,5-, 3,5- and 2,6-diethoxyphenyl, 2,4,6-triethoxyphenyl, 2-, 3- and 4-propoxyphenyl, 2,4-, 2,5-, 3,5- and 2,6-dipropoxyphenyl, 2-, 3- and 4-isopropoxyphenyl, 2,4-, 2,5-, 3,5- and 2,6-diisopropoxyphenyl and 2-, 3- and 4-butoxyphenyl; 2-, 3- and 4-cyanophenyl, and the like.

The above remarks regarding aryl also apply to the aryl moiety in aryloxy and arylsulfanyl (also referred to as arylthio).

Representative examples of aryloxy include phenoxy and naphthyloxy. Substituted aryloxy may, depending on the number and size of their ring systems, have one or more (e.g. 1, 2, 3, 4, 5 or more than 5) substituents independently selected from the substituents R^{aa} as defined above. Representative examples of arylthio include phenylthio (also referred to as phenylsulfanyl) and naphthylthio. Substituted arylthio may, depending on the number and size of their ring systems, have one or more (e.g. 1, 2, 3, 4, 5 or more than 5) substituents independently selected from the substituents R^{aa} as defined above.

In the context of the present invention, the term “hetaryl” (also referred to as heteroaryl) refers to heteroaromatic mono- or polycyclic radicals comprising, in addition to ring carbon atoms, 1, 2, 3, 4 or more than 4 heteroatoms as ring members. The heteroatoms are preferably selected from oxygen, nitrogen, selene and sulphur. Preferably, hetaryl denotes a radical having 5 to 18, for example 5, 6, 8, 9, 10, 11, 12, 13 or 14 ring members. The hetaryl radical may be attached to the remainder of the molecule via a carbon ring member or via a nitrogen ring member.

If hetaryl is a monocyclic radical, examples are 5- or 6-membered hetaryl such as 2-furyl(furan-2-yl), 3-furyl(furan-3-yl), 2-thienyl(thiophen-2-yl), 3-thienyl(thiophen-3-yl), selenophen-2-yl, selenophen-3-yl, 1H-pyrrol-2-yl, 1H-pyrrol-3-yl, pyrrol-1-yl, imidazol-2-yl, imidazol-1-yl, imidazol-4-yl, pyrazol-1-yl, pyrazol-3-yl, pyrazol-4-yl, pyrazol-5-yl, 3-isoxazolyl, 4-isoxazolyl, 5-isoxazolyl, 3-isothiazolyl, 4-isothiazolyl, 5-isothiazolyl, 2-oxazolyl, 4-oxazolyl, 5-oxazolyl, 2-thiazolyl, 4-thiazolyl, 5-thiazolyl, 1,2,4-oxadiazol-3-yl, 1,2,4-oxadiazol-5-yl, 1,3,4-oxadiazol-2-yl, 1,2,4-thiadiazol-3-yl, 1,2,4-thiadiazol-5-yl, 1,3,4-thiadiazol-2-yl, 4H-[1,2,4]-triazol-3-yl, 1,3,4-triazol-2-yl, 1,2,3-triazol-1-yl, 1,2,4-triazol-1-yl, pyridin-2-yl, pyridin-3-yl, pyridin-4-yl, 3-pyridazinyl, 4-pyridazinyl, 2-pyrimidinyl, 4-pyrimidinyl, 5-pyrimidinyl, 2-pyrazinyl, 1,3,5-triazin-2-yl and 1,2,4-triazin-3-yl. Preferred monocyclic hetaryl radicals include 2-furyl, 3-furyl, 2-thienyl, 3-thienyl, 1H-pyrrol-2-yl, 1H-pyrrol-3-yl, thiazol-2-yl, thiazol-5-yl, [1,3,4]thiadiazol-2-yl and 4H[1,2,4]-triazol-3-yl.

If hetaryl is a polycyclic radical, hetaryl has multiple rings (e.g. bicyclic, tricyclic, tetracyclic hetaryl), which are fused together. The fused-on ring may be aromatic, saturated or partially unsaturated. Examples of polycyclic hetaryl are quinolinyl, isoquinolinyl, indolyl, isoindolyl, indolizinyl, benzofuranyl, isobenzofuranyl, benzothiophenyl, benzoxazolyl, benzisoxazolyl, benzthiazolyl, benzoxadiazolyl; benzothiadiazolyl, benzoxazinyl, benzopyrazolyl, benzimidazolyl, benzotriazolyl, benzotriazinyl, benzoselenophenyl, thienothiophenyl, thienopyrimidyl, thiazolothiazolyl, dibenzopyrrolyl(carbazolyl), dibenzofuranyl, dibenzothiophenyl, naphtho[2,3-b]thiophenyl, naphtha[2,3-b]furyl, dihydroindolyl, dihydroindolizinyl, dihydroisoindolyl, dihydrochinolinyl, dihydroisochinolinyl.

In the case of substituted hetaryl radicals, the substitution is usually on at least one carbon and/or nitrogen ring atom(s). Suitable substituents of the hetaryl radicals are independently selected from the substituents R^{aa} as defined above. It is a matter of course that the maximum possible number of substituents depends on the size and number of heteroaromatic rings. The number of possible substituents ranges usually from 1 to more than 5, for example 1, 2, 3, 4, 5 or 6.

In the context of the present invention the expression “5-membered sulphur containing hetaryl which may contain additionally 1 or 2 nitrogen atoms as ring members and may carry a fused-on arene ring” denotes hetaryl having carbon atoms and one sulphur atom and optionally one or two nitrogen atoms within the 5-membered ring, wherein the 5 membered ring is optionally fused with one or two arene rings. Preferably the 5 membered ring does not carry a fused-on arene ring or is fused with one arene ring. The fused on arene rings are preferably selected from benzene, naphthalene, phenanthrene or anthracene. Examples are 2-thienyl, 3-thienyl, 2-thiazolyl, 4-thiazolyl, 5-thiazolyl, 3-isothiazolyl, 4-isothiazolyl, 5-isothiazolyl, 1,2,4-thiadiazol-3-yl, 1,2,4-thiadiazol-5-yl, 1,3,4-thiadiazol-2-yl, benzo[b]thienyl, benzthiazolyl, benzothiadiazolyl, naphtho[2,3-b]thiophenyl or dibenzo[b,d]thiophenyl.

In the context of the present invention, the expression “oligo(het)aryl” group refers to unsubstituted or substituted oligomers having at least one repeat unit. The repeat unit is selected from an arenediyl group and a hetarenediyl group. Accordingly, in one embodiment the repeat unit consists of at least one arenediyl group, in another embodiment the repeat unit consists of at least one hetarenediyl group and in a further embodiment the repeat unit consists of at least one arenediyl group and at least one hetarenediyl group. The arenediyl group is a divalent group derived from an arene, preferably benzene or naphthalene such as 1,2-phenylene (o-phenylene), 1,3-phenylene (m-phenylene), 1,4-phenylene (p-phenylene), 1,2-naphthylene, 2,3-naphthylene, 1,4-naphthylene and the like. The arenediyl group is a divalent group derived from a hetarene. Preferably, the hetarenediyl group is a divalent group derived from thiophene or furan.

The repeat unit is usually terminated with a monovalent group derived from the repeat unit. Each arenediyl group, each hetarenediyl group and the terminal group may be unsubstituted or substituted by 1, 2, 3, 4 or more than 4 substituents R^{aaa}. R^{aaa} at each occurrence is selected from alkyl, halogen, haloalkyl, alkoxy and haloalkoxy, preferably alkyl. The repeat units are bonded to another via a single bond. In the case of the thiophendiyl group and the furandiyl group, these groups are preferably covalently linked at the 2 position. The number of repeat units usually is in the range from 2, 3, 4, 5, 6, 7, 8 or more than 8, preferably 2, 3 or 4. In the following, oligo(het)aryl groups comprising at least one hetarenediyl group are also referred to as oligohetaryl groups.

Herein below, examples of repeat units are illustrated:

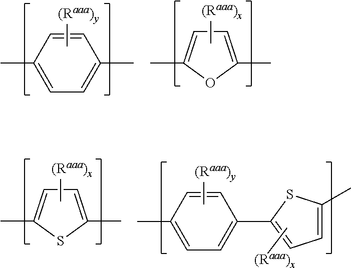

wherein R^{aaa} is as defined above, preferably alkyl, especially C₁-C₁₀-alkyl, x is 0, 1 or 2 and y is 0, 1, 2, 3 or 4.

Examples of oligo(het)aryl groups are

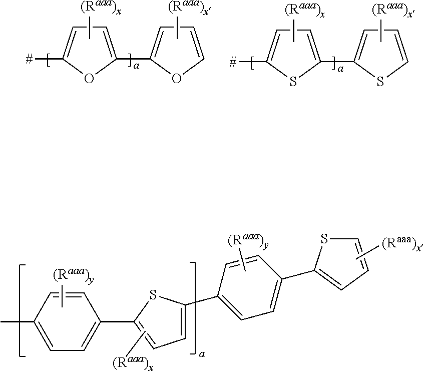

wherein # is the point of attachment to the remainder of the molecule, a is 1, 2, 3, 4, 5, 6, 7, or 8, y is 0, 1, 2, 3 or 4, x is 0, 1, 2 and x′ is 0, 1, 2 or 3 and R^{aaa} is as defined above.

Preferred examples of oligo(het)aryl groups are biphenylyl, p-terphenylyl, m-terphenylyl, o-terphenylyl, quaterphenylyl, e.g. p-quaterphenylyl, quinquephenylyl, e.g. p-quinquephenylyl and 2,2′-bifuran-5-yl.

Preferred examples of oligo(het)aryl groups are also unsubstituted oligothiophenyl groups of the formula

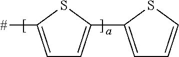

wherein # is the point of attachment to the remainder of the molecule and a is 1, 2, 3, 4, 5, 6, 7, or 8. A preferred example is 2,2′-bithiophen-5-yl.

Preferred examples of oligo(het)aryl groups are also substituted oligothiophenyl groups of the formula

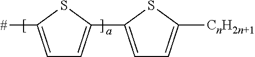

wherein # is the point of attachment to the remainder of the molecule and a is 1, 2, 3, 4, 5, 6, 7, or 8. A preferred example is 5″-hexyl-2′,2″-bithiophen-5-yl.

In the context of the present invention, carboxylate is a derivative of a carboxylic acid function, in particular a metal carboxylate, a carboxylic ester function such as —CO₂R′ with R′ being an alkyl group or aryl group, or a carboxamide function. Sulfonate is a derivative of a sulfonic acid function, in particular a metal sulfonate, a sulfonic acid ester function or a sulfonamide function.

As used herein a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

In the context of organic materials, the terms “donor” and “acceptor” refer to the relative positions of the HOMO and LUMO energy levels of two contacting but different organic materials. The term “electron donor” refers to the material's electron affinity. An electron donor material has a relative low electron affinity, i.e. the EA value has a smaller absolute value. As such, an electron donor material tends to act as a p-type material. In other words, an electron donor material may act as a hole transport material. The term “electron acceptor” refers to the material's electron affinity. An electron acceptor material has a relative high electron affinity. As such, an electron acceptor material tends to act as a n-type material. In other words, an electron acceptor material may act as an electron transport material.

The term “charge transport material” as used herein refers to a material which transports charge, i.e. holes or electrons. An electron donor material transports holes and an electron acceptor material transports electrons.

The term “photoactive region” as used herein is a portion of a photosensitive device that absorbs electromagnetic radiation to generate excitons (i.e. electrically neutral excited state in form of electron-hole pairs).

In general, compounds of the formulae Ia and Ib, carrying substituents on more than one fused arene ring A, e.g. on 2, 3 or 4 fused arene rings A, may exist as a mixture of regioisomers or as a single compound. In some cases several kinds of regioisomers may be present. In the present invention, the compound of the formulae Ia or Ib may be used as a single compound or as a mixture of regioisomers. In the case where a mixture of regioisomers is used, any number of regioisomers, any substitution positions in the isomer and any ratio of isomers may be used. All regioisomer forms of a compound of formulae Ia and Ib are intended, unless the specific isomeric form is specially indicated.

The remarks made in the following with respect to preferred aspects of the invention, e.g. to preferred meanings of the variables of compound of the formulae Ia or Ib, apply in each case on their own or to combinations thereof.

According to one embodiment of the invention, preference is given to compounds of the formula Ia.

According to a further embodiment of the invention, preference is given to compounds of the formula Ib. Preference is given to those compounds of formula Ib, wherein M is a divalent metal. Divalent metals may, for example, be chosen from those of groups 2, 8, 10, 11, 12 and 14 of the Periodic Table. Divalent metals are, for example, Cu(II), Zn(II), Fe(II), Ni(II), Cd(II), Ag(II), Mg(II), Sn(II), or Pb (II). Particular preference is given to compounds of the formula Ib, wherein M is Zn(II) or Cu(II), especially Zn (II).

Preference is also given to those compounds of the formula Ib, wherein M is a divalent metal atom containing group. A divalent metal atom containing group may, for example, be chosen from a divalent oxometal, a divalent hydroxymetal, or a divalent halogenometal moiety. In the divalent oxometal moiety, for example, the metal may be chosen from those of groups 4, 5, 7 and 14 of the Periodic Table. Examples of divalent oxometal moieties are V(IV)O, Mn(IV)O, Zr(IV)O, Sn(IV)O or Ti(IV)O. In a divalent hydroxymetal moiety, the metal may be chosen from those of groups 4, 6, 13, 14 and 15 of the Periodic Table. Examples of divalent hydroxymetal moieties are Al(III)OH, Cr(III)OH, Bi(III)OH, or Zr(IV)(OH)₂. In a divalent halogenometal moiety, the metal may be chosen from those of group 13 of the Periodic Table. Examples of divalent halogenometal moieties are for example, for example, Al(III)Cl, Al(III)F, In(III)F or In(III)Cl.

Preference is also given to those compounds of the formula Ib, wherein M is a divalent metalloid moiety. In divalent metalloid moieties, the metalloid may be chosen from a metalloid of group 14 of the Periodic Table, e.g. silicon. With a tetravalent metalloid, two of the valences may be satisfied by ligands such as hydrogen, hydroxy, halogen, e.g. fluorine or chlorine, alkyl, alkoxy, aryl or aryloxy. Examples of divalent metalloid moieties are SiH₂, SiF2, SiCl₂, Si(OH)₂, Si(alkyl)₂, Si(aryl)₂, Si(alkoxy)₂ and Si(aryloxy)₂.

Most preferred are compounds of the formula Ib, wherein M is Cu(II), Zn(II), Al(III)F, Al(III)Cl, especially Zn(II).

In the compounds of the formulae Ia and Ib, the fused-on rings A may have the same definition or different definitions.

Preference is given to those compounds of the formulae Ia and Ib, wherein all fused-on rings A have the same definition.

In the compounds of the formulae Ia or Ib, wherein all rings A are each a fused benzene ring, the substituents (R^{a})ₘ and (R^{b})ₙ, if present, may be located at any aromatic carbon of the fused benzene ring (the numbered positions on the benzene ring substructure indicate the positions where the substituent(s) (R^{a})ₘ and (R^{b})ₙ may be covalently bonded). These compounds are also referred to as Ia-Pc or Ib-Pc.

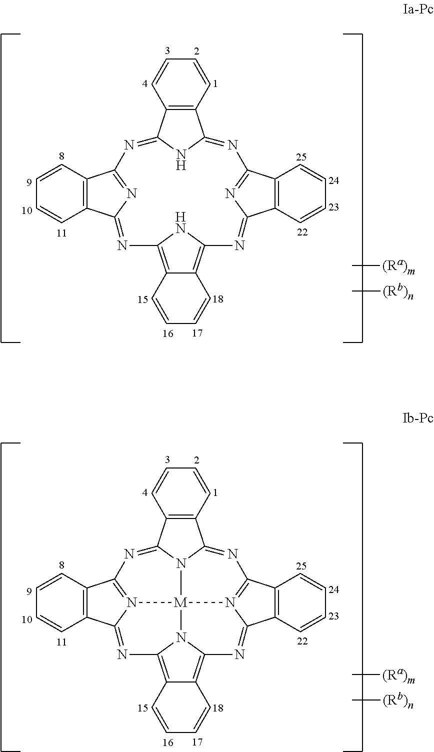

There are four possible positions for substitution on each of the benzene ring substructure. There are two possible linkage sites on each benzene ring substructure for substitution at the ortho position, namely the 1 and 4 position on the first benzene ring substructure, the 8 and 11 position on the second benzene ring substructure, the 15 and 18 position on the third benzene ring substructure and the 22 and 25 position on the fourth benzene ring substructure. Likewise, there are two possible linkage sites on each benzene ring substructure for substitution at the meta position, namely the 2 and 3 position on the first benzene ring substructure, the 9 and 10 position on the second benzene ring substructure, the 16 and 17 position on the third benzene ring substructure and the 23 and 24 position on the fourth benzene ring substructure.

Thus, a compound of the formulae Ia-Pc or Ib-Pc, referred to as 1,8(11),15(18),22(25)-tetrasubstituted phthalocyanine compound, denotes a compound of the formulae Ia-Pc or Ib-Pc carrying 4 substituents R^{a}, namely one substituent R^{a} in the 1 position, a further substituent R^{a} either in the 8 or 11 position, a further substituent R^{a} either in the 15 or 18 position and a further substituent R^{a} either in the 22 or 25 position. These compounds are also referred to as ortho-tetrasubstituted phthalcyanine compounds or as compounds of the formulae Ia-oPc or Ib-oPc.

Likewise, a compound of the formulae Ia-Pc or Ib-Pc, referred to as 2,9(10),16(17),23(24)-tetrasubstituted phthalocyanine compound, denotes a compound of the formulae Ia-Pc or Ib-Pc carrying 4 substituents R^{a}, namely one substituent R^{a} in the 2 position, a further substituent R^{a} either in the 9 or 10 position, a further substituent either in the 16 or 17 position and a further substituent R^{a} either in the 23 or 24 position. These compounds are also referred to as meta-tetrasubstituted phthalcyanine compounds or as compounds of the formulae Ia-mPc or Ib-mPc.

Examples of compounds of the formulae Ia or Ib, wherein all rings A are each a fused naphthalene ring, include the following:

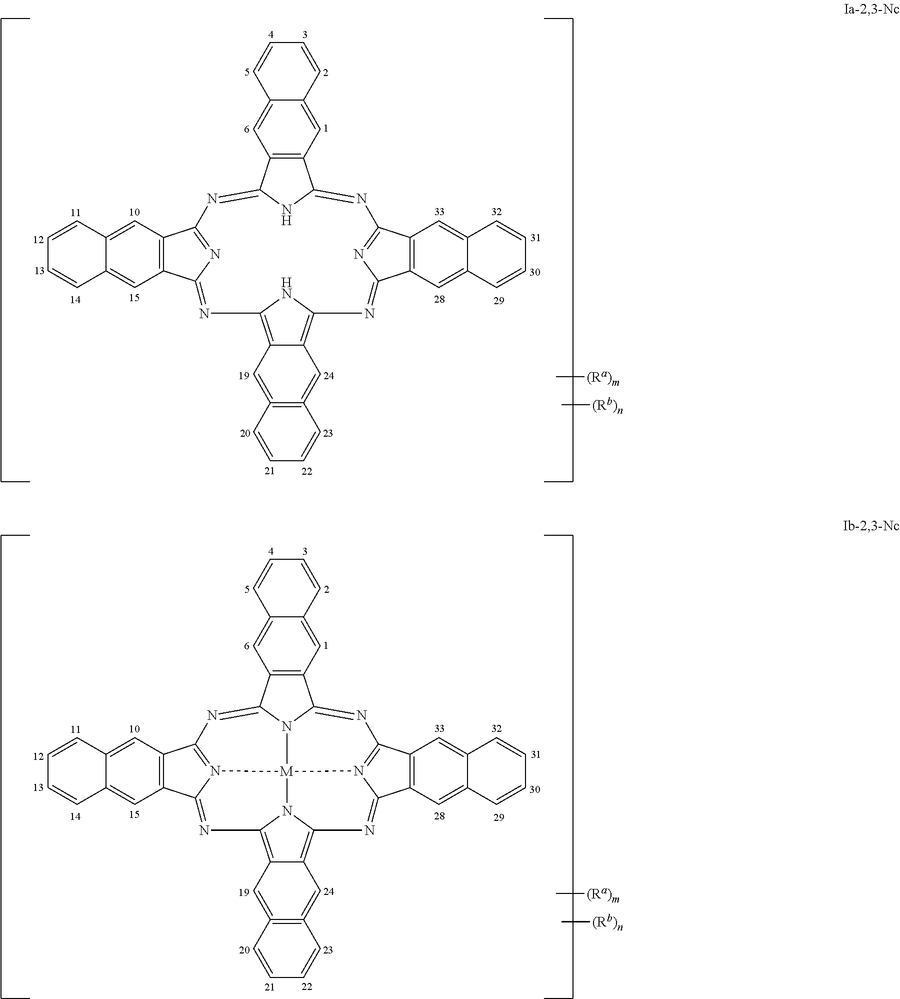

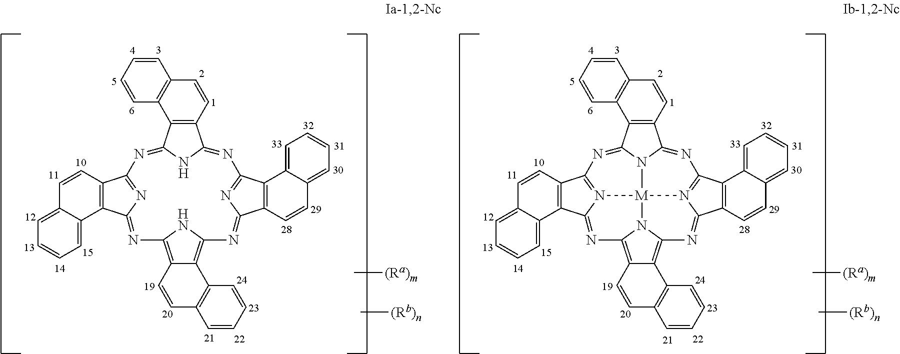

The substituent(s) (R^{a})ₘ and (R^{b})ₙ, if present, may be located at any aromatic carbon of the naphthalene substructure (the formulae of compounds Ia-2,3-Nc or Ib-2,3-Nc and Ia-1,2-Nc or Ib-1,2-Nc show the numbering of the naphthalene ring system present).

In compounds Ia-2,3-Nc or Ib-2,3-Nc, the substituent(s) (R^{a})ₘ and (R^{b})ₙ, if present, may be located, for example, at the peripheral positions (2, 3, 4, 5, 11, 12, 13, 14, 20, 21, 22, 23, 29, 30, 31 or 32) and/or at any of the inner positions (1, 6, 10, 15, 19, 24, 28 or 33). Preference is given to those compounds of the formulae Ia-2,3-Nc and Ib-2,3-Nc, where the substituent(s) (R^{a})ₘ and (R^{b})ₙ, if present, are located at inner positions (1, 6, 10, 15, 19, 24, 28 or 33).

In the compounds of the formulae Ia-1,2-Nc or Ib-1,2-Nc, the substituent(s) (R^{a})ₘ and (R^{b})ₙ, if present, may be located at any aromatic carbon of the naphthalene substructure, for example at any of the peripheral positions (3, 4, 5, 6, 12, 13, 14, 15, 21, 22, 23, 24, 30, 31, 32, 33) and/or at any of the inner positions (1, 2, 10, 11, 19, 20, 28, 29). Preference is given to those compounds of the formulae Ia-1,2-Nc and Ib-1,2-Nc, where the substituent(s) (R^{a})ₘ and (R^{b})ₙ, if present, are located at inner positions (1, 2, 10, 11, 19, 20, 28, 29).

Examples of compounds of the formula Ia or Ib, wherein all rings A are a fused anthracene ring include the following:

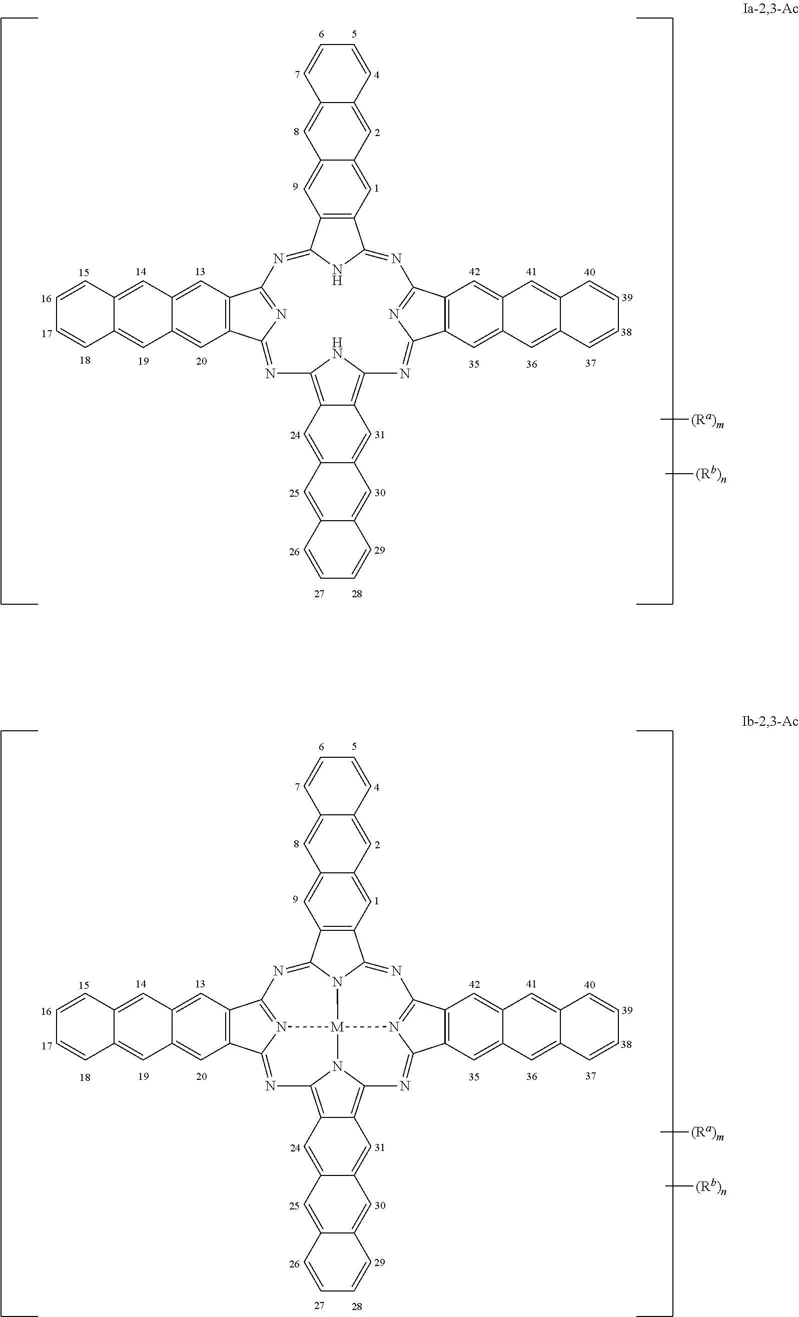

These compounds are also referred to as Ia-2,3-Ac and Ib-2,3-Ac. The substituent(s) (R^{a})ₘ and (R^{b})ₙ, if present, may be located at any aromatic carbon of the anthracene substructure (the numbered positions on the anthracene ring substructure indicate the positions where the substituent(s) (R^{a})ₘ and (R^{b})ₙ may be covalently bonded). The substituent(s) (R^{a})ₘ and (R^{b})ₙ may be located, for example, at the peripheral positions (4, 5, 6, 7, 15, 16, 17, 18, 26, 27, 28, 29, 37, 38, 39, and/or 40) and/or at any of the inner positions (1, 2, 8, 9, 13, 14, 19, 20, 24, 25, 30, 31, 35, 36, 41 and/or 42). Preference is given to those compounds of the formulae Ia-2,3-Ac and Ib-2,3-Ac, where the substituent(s) (R^{a})ₘ and (R^{b})ₙ, if present, are located at inner positions (1, 2, 8, 9, 13, 14, 19, 20, 24, 25, 30, 31, 35, 36, 41 and/or 42).

Examples of compounds of the formula Ia or Ib, wherein all rings A are a fused phenanthrene ring include the following:

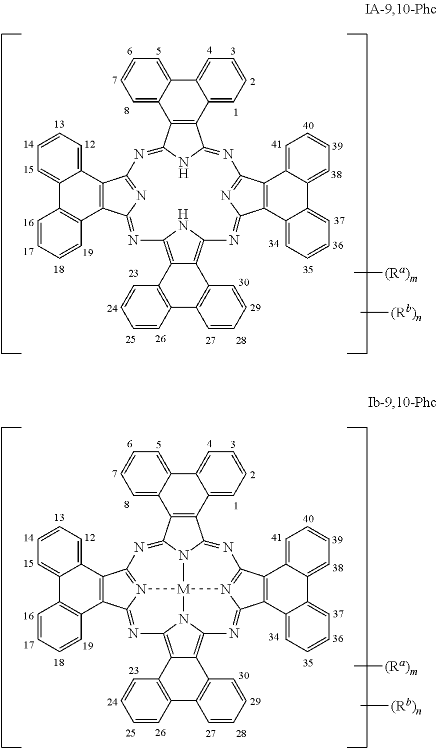

These compounds are also referred to as Ia-9,10-Phc and Ib-9,10-Phc. The substituent(s) (R^{a})ₘ and (R^{b})ₙ, if present, may be located at any aromatic carbon of the phenanthrene substructure (the numbered positions on the phenanthrene ring substructure indicate the positions where the substituent(s) (R^{a})ₘ and (R^{b})ₙ may be covalently bonded). The substituent(s) (R^{a})ₘ and (R^{b})ₙ may be located e.g. at the positions 1, 2, 3, 4, 5, 6, 7, 8, 12, 13, 14, 15, 16, 17, 18, 19, 23, 24, 25, 26, 28, 29, 30, 34, 36, 37, 38, 39, 40 and/or 41.

More preferred are compounds of the formulae Ia and Ib, wherein all rings A are a fused benzene ring.

Preference is given to compounds of the formulae Ia and Ib, wherein R^{a}, at each occurrence, is selected from phenyl, phenyloxy, phenylthio, naphthyl, naphthyloxy, naphthylthio, anthracenyl, anthracenyloxy, anthracenylthio, oligothiophenyl or hetaryl, e.g. 5-, 6-, 8-, 9- or 10-membered hetaryl, containing 1, 2 or 3 heteroatoms selected from the group consisting of O, N, Se and S as ring members. Phenyl, the phenyl moiety of phenyloxy and phenylthio, napthyl, the naphthyl moiety of naphthyloxy and naphthylthio, anthracenyl, the anthracenyl moiety of antracenyloxy and anthracenylthio, the thiophenyl moieties of oligothiophenyl and hetaryl may each be unsubstituted or are substituted by 1, 2, 3 or 4 substituents, independently selected from substituents R^{aa} as defined above.

Hetaryl groups R^{a}, containing 1, 2 or 3 heteroatoms selected from the group consisting of O, N, and S as ring members, are preferably selected from 2-furyl, 3-furyl, 2-thienyl, 3-thienyl, 1-pyrrolyl, 2-pyrrolyl, 3-pyrrolyl, 3-isothiazolyl, 4-isothiazolyl, 5-isothiazolyl, 3-pyrazolyl, 4-pyrazolyl, 5-pyrazolyl, 2-thiazolyl, 4-thiazolyl, 5-thiazolyl, 1-imidazolyl, 2-imidazolyl, 4-imidazolyl, 1,2,4-thiadiazol-3-yl, 1,2,4-thiadiazol-5-yl, 1,3,4-thiadiazol-2-yl, 1,2,5-thiadiazol-3-yl, 1,2,3-thiadiazol-4-yl, 1,2,3-thiadiazol-5-yl, 1,2,4-triazol-3-yl, 1,3,4-triazol-2-yl, 2-thienothiophenyl, 3-thienothiophenyl, 2-benzo[b]thienyl, 3-benzo[b]thienyl, 2-benzofuryl, 3-benzofuryl, 2-thiazolothiazolyl or 1,3-benzothiazol-2-yl.

More preference is given to compounds of the formulae Ia and Ib, wherein R^{a}, at each occurrence, is selected from phenyl, naphthyl, anthracenyl, phenyloxy, phenylthio, naphthyloxy, naphthylthio, oligothiophenyl and 5-membered sulphur containing hetaryl which may contain additionally 1 or 2 nitrogen atoms as ring members and may carry 1 or 2 fused-on arene rings and wherein phenyl, phenyloxy, phenylthio, naphthyl, naphthyloxy, naphthylthio, anthracenyl, oligothiophenyl and sulphur containing hetaryl are unsubstituted or substituted by 1 or 2 substituents R^{aa} selected from halogen, C₁-C₁₀-alkyl and C₁-C₁₀-haloalkyl.

Preferred meanings of R^{a} are unsubstituted phenyl, phenyl, which is monosubstituted by halogen, phenyl which is disubstituted by halogen such as 2,5-dichlorophenyl, phenyl, which is monosubstituted by C₁-C₁₀-alkyl such as 4-methylphenyl, 4-ethylphenyl, 4-n-propylphenyl, 4-isopropylphenyl, 4-n-butylphenyl, 4-sec-butylphenyl, 4-tert-butylphenyl, 4-neopentylphenyl, 1-naphthyl, 9-anthracenyl, oligohetaryl such as 2′,2″-bithiophenyl or 2-thienyl substituted by thienyl which for its part carries a C₁-C₁₀-alkyl group, such as, 5″-(C₁-C₁₀-alkyl)-2′,2″-bithiophenyl, especially 5″-n-hexyl-2′,2″-bithiophenyl, and 5-membered sulphur containing hetaryl which may contain additionally 1 or 2 nitrogen atoms as ring members and may carry a fused-on arene ring such as 2-thienyl, 3-thienyl, thiazol-2-yl, thiazol-5-yl, [1,3,4]thiadiazol-2-yl, benzo[b]thienyl, especially benzo[b]thiophen-2-yl.

Likewise, preferred meanings of R^{a} are phenoxy, phenylthio, naphthyloxy, especially 1-naphthyloxy or naphthylthio, especially 1-naphthylthio, phenoxy substituted by C₁-C₄-haloalkyl, especially fluoroalkyl, such as 4-trifluoromethylphenoxy, in particular phenoxy.

Most preference is given to compounds of the formulae Ia and Ib, wherein R^{a}, at each occurrence, is selected from phenoxy, 1-naphthyl, 2-thienyl, 3-thienyl, benzo[b]thiophen-2-yl, unsubstituted phenyl or phenyl which is substituted by C₁-C₄-alkyl, especially 4-tert-butylphenyl. Very preferred examples of substituents R^{a} are phenyl, 2-thienyl, and 3-thienyl, especially 2-thienyl.

The substituent(s) R^{a} may be located at any aromatic position of the fused arene ring A. In the case that the compounds of the formulae Ia and Ib carry more than one substituent R^{a}, they may the same or different. Preferably, all substituents R^{a} have the same meaning. Preferably, each ring A carries the same number of substituents R^{a}. More preferably, all substituents R^{a} have the same meaning and each ring A carries the same number of substituents R^{a}.

The index m in compounds of the formulae Ia and Ib is preferably 1, 2, 3, 4, 5, 6, 7 or 8, more preferably 4 or 8. In the case that each A is a fused benzene ring, m is preferably 1, 2, 3, 4, 5, 6, 7 or 8, preferably 4 or 8. Each R^{a} is preferably located at any of the two ortho-positions of the benzene ring. Most preference is given to those compounds of formulae Ia and Ib, wherein each ring A is a benzene ring and each benzene ring carries one substituent R^{a} in the ortho-position, i.e. m is 4.

In the case that each A is a fused naphthalene ring, m is preferably 1, 2, 3, 4, 5, 6, 7 or 8, preferably 4 or 8. Preferably, each R^{a} is located at an inner position. In the case of the compounds of formulae Ia-2,3-Nc and Ib-2,3-Nc, the inner positions are the positions 1, 6, 10, 15, 19, 24, 28 and 33. In the case of the compounds of formulae Ia-1,2-Nc and Ib-1,2-Nc, the inner positions are the positions 1, 2, 10, 11, 19, 20, 28 and 29. Most preference is given to those compounds of formulae Ia and Ib, wherein each ring A is a naphthalene ring and each naphthalene ring carries one substituent R^{a} in the inner position, i.e. m is 4.

In the case that each A is a fused anthracene ring, m is preferably 1, 2, 3, 4, 5, 6, 7 or 8, preferably 4 or 8. Preferably, each R^{a} is located at an inner position. In the case of the compounds of formulae Ia-2,3-Ac and Ib-2,3-Ac, the inner positions are the positions 1, 2, 8, 9, 13, 14, 19, 20, 24, 25, 30, 31, 35, 36, 41 and 42. Most preference is given to those compounds of formulae Ia and Ib, wherein each ring A is an anthracene ring and each anthracene ring carries one substituent R^{a} at the inner position, i.e. m is 4.

The substituent(s) R^{b}, if present, may be located at any aromatic position of the fused arene ring A. In the case that the compounds of the formulae Ia and Ib carry more than one substituent R^{b}, they may have the same definition or different definitions. Preferably, all substituents R^{b} have the same definition.

Preferably, each ring A carries the same number of substituents R^{b}. More preferably, all substituents R^{b} have the same meaning and each ring A carries the same number of substituents R^{b}. The substituent R^{b} is preferably halogen, more preferably fluorine.

The index n in compounds of the formulae Ia and Ib is preferably zero.

According to a further embodiment of the invention particular preferred compounds of the formulae Ia and Ib are the compounds of the formulae Ia-oPc and Ib-oPc, i.e. compounds of the formulae Ia-Pc and Ib-Pc, wherein the index m is 4 and the index n is 0,

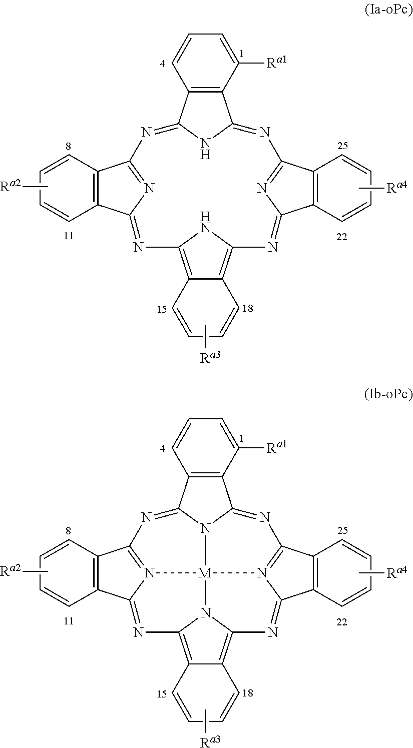

where
M in formula Ib is as defined above; and
R^{a1}, R^{a2}, R^{a3} and R^{a4} have one of the meanings given for R^{a};
the substituent R^{a2} being attached in position 8 or 11, the substituent R^{a3} being attached in position 15 or 18 and the substituent R^{a4} being attached in position 22 or 25.

M in compounds of the formula Ib-oPc is preferably Zn(II), Cu(II), Al(III)F or Al(III)Cl, in particular Zn(II).

R^{a1}, R^{a2}, R^{a3} and R^{a4} are preferably independently of each other phenyl, phenoxy, phenylthio, naphthyl, naphthyloxy, naphthylthio, anthracenyl, oligohetaryl or 5-membered sulphur containing hetaryl which may contain additionally 1 or 2 nitrogen atoms as ring members and may carry one or two fused-on arene rings and wherein phenyl, phenoxy, phenylthio, naphthyl, naphthyloxy, naphthylthio, anthracenyl, and 5-membered sulphur containing hetaryl are unsubstituted or substituted by 1 or 2 substituents R^{aa} selected from halogen, C₁-C₁₀-alkyl and C₁-C₁₀-haloalkyl.

Preferably, 5-membered sulphur containing hetaryl is selected from 2-thienyl, 3-thienyl, thiazol-2-yl, thiazol-5-yl, [1,3,4]thiadiazol-2-yl and benzo[b]thienyl, especially benzo[b]thiophen-2-yl.

Most preference is given to compounds of the formulae Ia-oPc and Ib-oPc, wherein R^{a1}, R^{a2}, R^{a3} and R^{a4} are selected from phenoxy, 1-naphthyl, 2-thienyl, 3-thienyl, benzo[b]thiophen-2-yl, unsubstituted phenyl or phenyl which is substituted by C₁-C₄-alkyl, especially 4-tert-butylphenyl. Very preferred examples of substituents R^{a} are phenyl, 2-thienyl, and 3-thienyl, especially 2-thienyl.

Preferably R^{a1}, R^{a2}, R^{a3} and R^{a4} have the same definition.

Especially preferred are the compounds of the formula Ib-oPc, in which the variables M and R^{a1}, R^{a2}, R^{a3} and R^{a4} have in combination the following meanings:

### M is Zn(II), Cu(II), Al(III)F or Al(III)Cl;

R^{a1}=R^{a2}=R^{a3}=R^{a4} are phenyl,
are phenyl which is monosubstituted by halogen,
are phenyl which is disubstituted by halogen, especially chlorine, such as 2,5-dichlorophenyl,
are phenyl which is monosubstituted by C₁-C₁₀-alkyl such as 4-methylphenyl, 4-ethylphenyl, 4-n-propylphenyl, 4-isopropylphenyl, 4-n-butylphenyl, 4-sec-butylphenyl, 4-tert-butylphenyl, 4-neopentylphenyl,
are phenoxy,
are phenoxy which is substituted by C₁-C₄-haloalkyl, especially C₁-C₄-fluoroalkyl, such as 4-trifluoromethylphenoxy,
are phenylthio,
are naphthyl, especially 1-naphthyl,
are naphthyloxy, especially 1-naphthyloxy,
are naphthylthio, especially 1-naphthylthio,
are anthracenyl, especially 9-anthracenyl,
are oligohetaryl such as 2′,2″-bithiophenyl or 2-thienyl substituted by thienyl which for its part is substituted by C₁-C₁₀-alkyl such as, 5″-(C₁-C₁₀-alkyl)-2′,2″-bithiophenyl, especially 5″-n-hexyl-2′,2″-bithiophenyl, or
are 5-membered sulphur containing hetaryl which may contain additionally 1 or 2 nitrogen atoms as ring members and may carry a fused-on arene ring such as 2-thienyl, 3-thienyl, thiazol-2-yl, thiazol-5-yl, [1,3,4]thiadiazol-2-yl, benzo[b]thienyl, especially benzo[b]thiophen-2-yl.

Even more particular preference is given to those compounds of the formula Ib-oPc, in which the variables M and R^{a1}, R^{a2}, R^{a3} and R^{a4} have in combination the following meanings:

### M is Zn(II);

R^{a1}=R^{a2}=R^{a3}=R^{a4} are phenyl,
are phenyl which is monosubstituted by C₁-C₆-alkyl, especially 4-tert-butylphenyl,
are phenoxy,
are naphthyl, especially 1-naphthyl,
are 2-thienyl,
are 3-thienyl,
are thiazol-2-yl,
are thiazol-5-yl,
are benzo[b]thiophen-2-yl.

Even more particular preference is given to those compounds of the formula Ib-oPc, in which the variables M and R^{a1}, R^{a2}, R^{a3} and R^{a4} have in combination the following meanings:

### M is Cu(II);

R^{a1}=R^{a2}=R^{a3}=R^{a4} are phenyl,
are phenyl which is monosubstituted by C₁-C₆-alkyl, especially 4-tert-butylphenyl,
are phenoxy,
are naphthyl, especially 1-naphthyl,
are 2-thienyl,
are 3-thienyl,
are thiazol-2-yl,
are thiazol-5-yl,
are benzo[b]thiophen-2-yl.

Most preferred compounds of the formula Ib-oPc include:
ortho-tetraphenyl zincphthalocyanine,
ortho-tetranaphthyl zincphthalocyanine,
ortho-tetrakis[4-(tert-butyl)phenyl]zincphthalocyanine,
ortho-tetraphenoxy zincphthalocyanine,
ortho-tetrathien-2-yl zincphthalocyanine,
ortho-tetrathien-3-yl zincphthalocyanine,
ortho-tetrabenzo[b]thiophen-2-yl zincphthalocyanine,
ortho-tetraphenyl copperphthalocyanine,
ortho-tetranaphthyl copperphthalocyanine,
ortho-tetrakis[4-(tert-butyl)phenyl]copperphthalocyanine,
ortho-tetraphenoxy copperphthalocyanine,
ortho-tetrathien-2-yl copperphthalocyanine,
ortho-tetrathien-3-yl copperphthalocyanine and
ortho-tetrabenzo[b]thiophen-2-yl copperphthalocyanine.

In an alternative embodiment, in compounds of formulae Ia and Ib the index n is 1, 2, 3, 4, 5, 6, 7, 8, 9, 10, 11, 12, 13, 14, 15, 16, 17, 18, 19, 20, 21, 22 or 23.

Preference is given to those compounds of the formulae Ia and Ib, wherein the index n is 1, 2, 3, 4, 5, 6, 7, 8, 9, 10, 11, 12, 13, 14, 15 or 16. In this case, each ring A preferably carries the same number of substituents R^{b}. Accordingly, a more preferred embodiment relates to compounds of the formulae Ia and Ib, wherein the index n is 4. A further more preferred embodiment relates to compounds of the formulae Ia and Ib, wherein the index n is 8. A further more preferred embodiment relates to compounds of the formulae Ia and Ib, wherein the index n is 12. Most preference is given to those compounds of formulae Ia and Ib, wherein each ring A has the same meaning and n is 4 or 8, especially 4. Among these, most preference is given to those compounds of formulae Ia and Ib, wherein each ring A is a benzene ring, each benzene ring has the same number of substituents R^{b}, n is 4 or 8 and (R^{a})ₘ has one of the meanings given above, in particular one of the meanings given as being preferred or as being particularly preferred. Likewise, most preference is given to those compounds of formulae Ia and Ib, wherein each ring A is a naphthalene ring, each naphthalene ring has the same number of substituents R^{b}, n is 4 or 8 and (R^{a})ₘ has one of the meanings given above, in particular one of the meanings given as being preferred or as being particularly preferred. Likewise, most preference is given to those compounds of formulae Ia and Ib, wherein each ring A is an anthracene ring, each anthracene ring has the same number of substituents R^{b}, n is 4 or 8 and (R^{a})ₘ has one of the meanings given above, in particular one of the meanings given as being preferred or as being particularly preferred. Likewise, most preference is given to those compounds of formulae Ia and Ib, wherein each ring A is a phenanthrene ring, each phenanthrene ring has the same number of substituents R^{b}, n is 4 or 8 and (R^{a})ₘ has one of the meanings given above, in particular one of the meanings given as being preferred or as being particularly preferred.

Among the compounds of formulae Ia and Ib, wherein the index n is 1, 2, 3, 4, 5, 6, 7, 8, 9, 10, 11, 12, 13, 14, 15, 16, 17, 18, 19, 20, 21, 22 or 23, particular preference is given to those compounds Ia and Ib, wherein R^{b} is fluorine. Herein below, these compounds are also referred to as compounds Ia-F and Ib-F.

Thus, according to a further embodiment of the invention, preference is given to compounds of formulae Ia-F and Ib-F

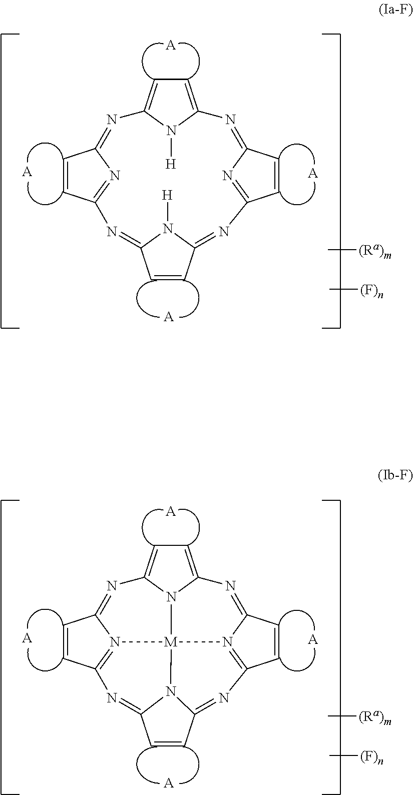

wherein
M is a divalent metal, a divalent metal atom containing group or a divalent metalloid group;
A at each occurrence, is a fused arene ring selected from a benzene ring, naphthalene ring, anthracene ring and phenanthrene ring;
R^{a} at each occurrence, is independently selected from aryl, aryloxy, arylthio, monoarylamino, diarylamino, hetaryl hetaryloxy, oligo(het)aryl or oligo(het)aryloxy, wherein each aryl, aryloxy, arylthio, monoarylamino, diarylamino, hetaryl, hetaryloxy, oligo(het)aryl or oligo(het)aryloxy may be unsubstituted or carries at least one substituents R^{aa} independently selected from cyano, hydroxyl, nitro, carboxyl, halogen, alkyl, cycloalkyl, haloalkyl, halocycloalkyl, alkoxy, haloalkoxy, alkylsulfanyl, haloalkylsulfanyl, amino, monoalkylamino, dialkylamino, NH(aryl) and N(aryl)₂;
m is an integer 1, 2, 3, 4, 5, 6, 7, 8, 9, 10, 11, 12, 13, 14, 15; and
n 1, 2, 3, 4, 5, 6, 7, 8, 9, 10, 11, 12, 13, 14, 15, 16, 17, 18, 19, 20, 21, 22 or 23.

Compounds of the formulae Ia-F and Ib-F are novel and form also part of the invention.

In a particular embodiment, the variables of the compounds of the formulae Ia-F and Ib-F have the meanings below, these meanings—both on their own and in combination with one another—being particular embodiments of the compounds of the formulae Ia-F and Ib-F:

n is preferably 4, 8 or 12, in particular 4 or 8.

M in compounds of the formula Ib-F is preferably Zn(II), Cu(II), Al(III)F or Al(III)Cl, in particular Zn(II).

Preference is given to those compounds of the formulae Ia-F and Ib-F, wherein all fused-on rings A have the same meaning. Especially preferred among these compounds are those, wherein each A is a fused benzene ring. Preferably, each A carries the same number of fluorine substituents. Preference is likewise given to compounds of the general formula Ia-F and Ib-F, wherein each A carries the same number of radicals R^{a}. Among these, each A carries 1 or 2 radicals R^{a}, especially 1 radical R^{a}. Among these, each A carries 1 or 2 radicals R^{a}, especially 1 radical R^{a} and 1 fluorine substituent.

R^{a} is preferably selected from phenyl, phenyloxy, phenylthio, naphthyl, naphthyloxy, naphthylthio, oligothiophenyl and hetaryl, wherein hetaryl contains 1, 2 or 3 heteroatoms selected from the group consisting of O, N, Se and S as ring members and wherein the phenyl moiety of phenyl, phenyloxy and phenylthio, the naphthyl moiety of naphthyl, naphthyloxy and naphthylthio, the thiophenyl moieties of oligothiophenyl and the hetaryl moiety are each unsubstituted or substituted by 1, 2, 3 or 4 substituents R^{aa}.

Hetaryl groups R^{a}, containing 1, 2 or 3 heteroatoms selected from the group consisting of O, N, and S as ring members, are preferably selected from 2-furyl, 3-furyl, 2-thienyl, 3-thienyl, 1-pyrrolyl, 2-pyrrolyl, 3-pyrrolyl, 3-isothiazolyl, 4-isothiazolyl, 5-isothiazolyl, 3-pyrazolyl, 4-pyrazolyl, 5-pyrazolyl, 2-thiazolyl, 4-thiazolyl, 5-thiazolyl, 1-imidazolyl, 2-imidazolyl, 4-imidazolyl, 1,2,4-thiadiazol-3-yl, 1,2,4-thiadiazol-5-yl, 1,3,4-thiadiazol-2-yl, 1,2,5-thiadiazol-3-yl, 1,2,3-thiadiazol-4-yl, 1,2,3-thiadiazol-5-yl, 1,2,4-triazol-3-yl, 1,3,4-triazol-2-yl, 2-thienothiophenyl, 3-thienothiophenyl, 2-benzo[b]thienyl, 3-benzo[b]thienyl, 2-benzofuryl, 3-benzofuryl, 2-thiazolothiazolyl or 1,3-benzothiazol-2-yl.

More preference is given to compounds of the formulae Ia-F and Ib-F, wherein R^{a}, at each occurrence, is selected from phenyl, naphthyl, anthracenyl, phenyloxy, phenylthio, naphthyloxy, naphthylthio, oligothiophenyl and 5-membered sulphur containing hetaryl which may contain additionally 1 or 2 nitrogen atoms as ring members and may carry 1 or 2 fused-on arene rings and wherein phenyl, phenyloxy, phenylthio, naphthyl, naphthyloxy, naphthylthio, anthracenyl, oligothiophenyl and sulphur containing hetaryl are unsubstituted or substituted by 1 or 2 substituents R^{aa} selected from halogen, C₁-C₁₀-alkyl and C₁-C₁₀-haloalkyl.

Preferred meanings of R^{a} are unsubstituted phenyl, phenyl, which is monosubstituted by halogen, phenyl which is disubstituted by halogen such as 2,5-dichlorophenyl, phenyl, which is monosubstituted by C₁-C₁₀-alkyl such as 4-methylphenyl, 4-ethylphenyl, 4-n-propylphenyl, 4-isopropylphenyl, 4-n-butylphenyl, 4-sec-butylphenyl, 4-tert-butylphenyl, 4-neopentylphenyl, 1-naphthyl, 9-anthracenyl, oligohetaryl such as 2′,2″-bithiophenyl or 2-thienyl substituted by thienyl which for its part carries a C₁-C₁₀-alkyl group, such as, 5″-(C₁-C₁₀-alkyl)-2′,2″-bithiophenyl, especially 5″-n-hexyl-2′,2″-bithiophenyl, and 5-membered sulphur containing hetaryl which may contain additionally 1 or 2 nitrogen atoms as ring members and may carry a fused-on arene ring such as 2-thienyl, 3-thienyl, thiazol-2-yl, thiazol-5-yl, [1,3,4]thiadiazol-2-yl, benzo[b]thienyl, especially benzo[b]thiophen-2-yl.

Likewise, preferred meanings of R^{a} are phenoxy, phenylthio, naphthyloxy, especially 1-naphthyloxy or naphthylthio, especially 1-naphthylthio, phenoxy substituted by C₁-C₄-haloalkyl, especially fluoroalkyl, such as 4-trifluoromethylphenoxy, in particular phenoxy.

Most preference is given to compounds of the formulae Ia-F and Ib-F, wherein R^{a}, at each occurrence, is selected from phenoxy, 1-naphthyl, 2-thienyl, 3-thienyl, benzo[b]thiophen-2-yl, unsubstituted phenyl or phenyl which is substituted by C₁-C₄-alkyl, especially 4-tert-butylphenyl. Very preferred examples of substituents R^{a} are phenyl, 2-thienyl, and 3-thienyl, especially 2-thienyl. Most preferably, each R^{a} has the same meaning.

Particularly preferred among the compounds of the formulae Ia-F and Ib-F are those compounds, wherein each A is a fused benzene ring and the substituents R^{a} and R^{b} are each located at the ortho-positions of each benzene substructure. The substituent R^{a} is attached in the positions 1, 8(11), 15(18) and 22(25) and the substituent F is attached in the positions 4, 11(8) or 15(11) and 25(22). It shall be understood that e.g., if R^{a} is located in the position 8, F is located in the position 11 and if R^{a} is located in the position 11, F is located in the position 8. These compounds are also referred to as Ia-o,oPcF and Ib-o,oPcF.

Likewise, particularly preferred among the compounds of the formulae Ia-F and Ib-F are those, wherein each A is a fused benzene ring, the substituents R^{a} and R^{b} are each located at the meta-positions of each benzene substructure. These compounds are also referred to as Ia-m,mPcF and Ib-m,mPcF.

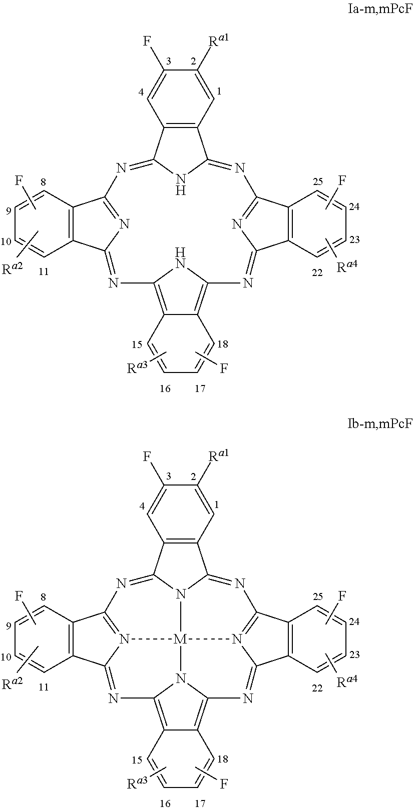

where
M in formula Ib-m,m-PcF is as defined above; and
R^{a1}, R^{a2}, R^{a3} and R^{a4} have one of the meanings given for R^{a}.
with R^{a1}, R^{a2}, R^{a3} and R^{a4} being attached in the positions 2, 9(10), 16(17) and 23(24) and the substituents F being attached in the positions 3, 10(9) or 16(17) and 24(23). It shall be understood that e.g., if R^{a2} is located in the position 9, F is located in the position 10 and if R^{a2} is located in the position 10, F is located in the position 9.

Among the compounds of the formulae Ia-m,mPcF and Ib-m,mPcF, very particular preferred are those compounds, wherein R^{a1}, R^{a2}, R^{a3} and R^{a4} are the same and have one of the meanings being preferred for R^{a}, in particular one of the meanings given as being as being particularly preferred, specially phenyl.

Compounds of the formula Ib-F can be prepared by various routes in analogy to prior art processes known per se for preparing fluorinated phthalocyanine compounds and, advantageously, by the synthesis shown in the following schemes and in the experimental part of this application.

A further object of the invention is a process for preparing compounds of the formulae Ib-F

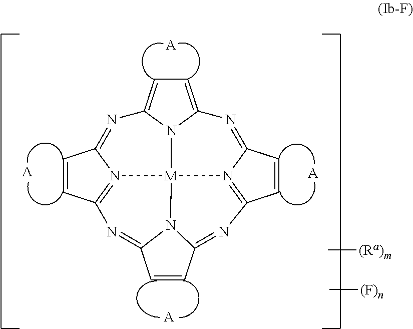

wherein
M is a divalent metal, a divalent metal atom containing group or a divalent metalloid group,
A at each occurrence, is a fused arene ring selected from a benzene ring, naphthalene ring, anthracene ring and phenanthrene ring,
R^{a} is aryl, aryloxy, arylthio, diarylamino or hetaryl, wherein each aryl, aryloxy, arylthio, diarylamino and hetaryl may be unsubstituted or carries at least one substituents R^{aa} independently selected from cyano, hydroxyl, nitro, carboxyl, halogen, alkyl, cycloalkyl, haloalkyl, halocycloalkyl, alkoxy, haloalkoxy, alkylsulfanyl, haloalkylsulfanyl, amino, monoalkylamino, dialkylamino, NH(aryl), N(aryl)₂, oligoaryl and oligohetaryl,
m is 1, 2, 3, 4, 5, 6, 7, 8, 9, 10, 11, 12, 13, 14 or 15 and
n is 1, 2, 3, 4, 5, 6, 7, 8, 9, 10, 11, 12, 13, 14, 15, 16, 17, 18, 19, 20, 21, 22 or 23;
   comprising
a) providing an educt composition which comprises at least one compound selected from compounds of the formulae IIa, IIb, IIc and IId

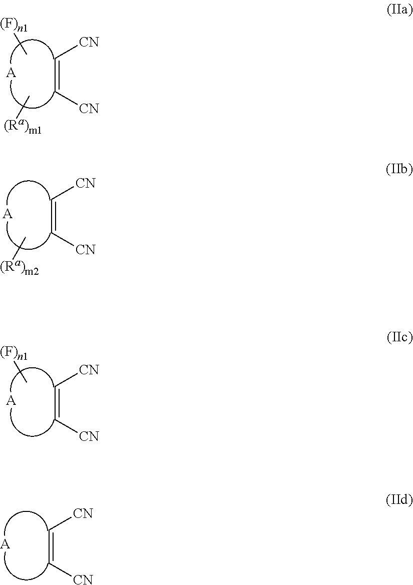

wherein
the groups A are, independently of each other, a fused arene ring selected from a benzene ring, naphthalene ring, anthracene ring and phenanthrene ring,
m₁ is 1, 2, 3 or 4,
m₂ is 1, 2, 3 or 4,
n₁ is 1, 2, 3, 4, 5, 6 or 7
n₃ is 0, 1, 2, 3, 4, 5, 6, 7 or 8,
with the proviso that the sum of all indices m₁ plus the sum of all indices m₂ is not more than 15,
with the proviso that the sum of all indices n₁ plus the sum of all indices n₂ is not more than 23,
with the proviso that the educt composition comprises which least one compound of the formula IIa or that the educt composition comprises at least one compound of the formula IIb and at least one compound of the formula IIc,
b) reacting the educt composition at an elevated temperature with a compound of a metal M.

Preferably, the educt composition provided in step a) consists only of compounds of the formula IIa. In a special embodiment, the educt composition provided in step a) consists only of one compound of the formula IIa.

Preferably, the educt composition provided in step a) comprises at least one compound of the formula IIa1

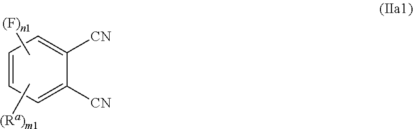

wherein m₁ is 1 or 2 and n₁ is 1 or 2.

In step a), the compounds of the formula (IIa) can be prepared by a Suzuki coupling reaction, as exemplified by the following scheme 1.

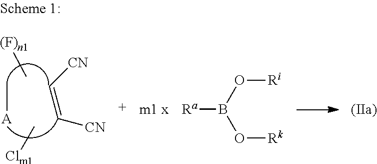

Preferably Rⁱ and R^{k} are each independently hydrogen or C₁-C₄-alkyl or Rⁱ and R^{k} together form an 1,2-ethylene or 1,2-propylene moiety the carbon atoms of which may be unsubstituted or may all or in part be substituted by methyl groups.

The Suzuki reaction is usually carried out in the presence of a catalyst, in particular a palladium catalyst, such as for example described in the following literature: Synth. Commun. Vol. 11, p. 513 (1981); Acc. Chem. Res. Vol. 15, pp. 178-184 (1982); Chem. Rev. Vol. 95, pp. 2457-2483 (1995); Organic Letters Vol. 6 (16), p. 2808 (2004); “Metal catalyzed cross coupling reactions”, 2nd Edition, Wiley, VCH 2005 (Eds. De Meijere, Diederich); “Handbook of organopalladium chemistry for organic synthesis” (Eds Negishi), Wiley, Interscience, New York, 2002; “Handbook of functionalized organometallics”, (Ed. P. Knochel), Wiley, VCH, 2005.

Suitable catalysts for the Suzuki reaction are in tetrakis(triphenylphosphine)-palladium(0); bis(triphenylphosphine)palladium(II) chloride; bis(acetonitrile)palladium(II) chloride; [1,1′-bis(diphenylphosphino)ferrocene]-palladium(II) chloride/methylene chloride (1:1) complex; bis[bis-(1,2-diphenylphosphino)ethane]palladium(0); bis(bis-(1,2-diphenylphosphino)butane]-palladium(II) chloride; palladium(II) acetate; palladium(II) chloride; and palladium(II) acetate/tri-o-tolylphosphine complex or mixtures of phosphines and Pd salts or phosphines and Pd-complexes e.g. tris(dibenzylideneacetone)dipalladium(0) (Pd₂(dba)₃) and tritertbutylphosphine (or its tetrafluoroborate), tris cyclohexylphosphine; or a polymer-bound Pd-triphenylphosphine catalyst system.

The Suzuki coupling is usually carried out in the presence of a base. Suitable bases are, in general, inorganic compounds, such as alkali metal and alkaline earth metal oxides, such as lithium oxide, sodium oxide, calcium oxide and magnesium oxide, alkali metal and alkaline earth metal carbonates, such as lithium carbonate, sodium carbonate, potassium carbonate, caesium carbonate and calcium carbonate, and also alkali metal bicarbonates, such as sodium bicarbonate, alkali metal and alkaline earth metal alkoxides, such as sodium methoxide, sodium ethoxide, potassium ethoxide and potassium tert.-butoxide, moreover organic bases, for example tertiary amines, such as trimethylamine, triethylamine, diisopropylethylamine and N-methylpiperidine, pyridine, substituted pyridines, such as collidine, lutidine and 4-dimethylaminopyridine, and also bicyclic amines. Particular preference is given to bases such as sodium carbonate, potassium carbonate, caesium carbonate, triethylamine and sodium bicarbonate.

The Suzuki reaction is usually carried out in an inert organic solvent. Suitable solvents are aliphatic hydrocarbons, such as pentane, hexane, cyclohexane and petroleum ether, aromatic hydrocarbons, such as toluene, o-, m- and p-xylene, ethers, such as diisopropyl ether, tert.-butyl methyl ether, dioxane, anisole and tetrahydrofuran and dimethoxyethane, ketones, such as acetone, methyl ethyl ketone, diethyl ketone and tert.-butyl methyl ketone, and also dimethyl sulfoxide, dimethylformamide and dimethylacetamide, particularly preferably ethers, such as tetrahydrofuran, dioxane and dimethoxyethane. It is also possible to use mixtures of the solvents mentioned, or mixtures with water.

The Suzuki reaction is usually carried out at temperatures of from 20° C. to 180° C., preferably from 40° C. to 120° C.

A skilled person will readily understand that compounds of formula IIb can be prepared in an analogous manner.

Preferably in step b), the reaction is carried out in the presence of a catalyst. The catalyst can be selected from ammonium molybdate, ammonium phosphomolybdate and molybdenum oxide. In the case of molybdenum oxide, it may be advantageous to to use a combination of molybdenum oxide/ammonia. Preference is given to using ammonium molybdate or molybdenum oxide/ammonia. The molar amount of the catalyst based on the total molar amount of compound (IIa) and compound (IIc), if present, usually is 0.01 to 0.5 times, preferably 0.02 to 0.2 times.

The metal compound employed in step b) is preferably a metal salt. Preferred metal salts can be selected from metal halides, especially metal chloride, metal salt of a C₁-C₆-carboxylic acid, especially metal acetate and metal sulfate. In particular, if a Zn salt is employed, the zinc salt is zinc acetate. The molar amount of the metal salt based on the total molar amount of dinitrile compound of the formula IIa, and, if present, of the formulae IIb, IIc and IId, usually is 0.3 to 0.5 times.

The reaction in step b) is preferably carried out in a solvent. Suitable solvents are organic solvents having a high boiling point, such as nitrobenzene, chlorinated benzene such as trichlorobenzene or chlorinated naphthalene and mixtures thereof. Particular preference is given to using nitrobenzene.

It may be advantageous to carry out the reaction under a protective gas atmosphere, for example nitrogen or argon.

The reaction in step b) is usually carried out at a temperature of from 80 to 300° C., preferably of from 100 to 250° C.

Scheme 2 exemplifies the formation of meta-tetrafluoro-meta-tetraphenyl zinc phthalocyanine:

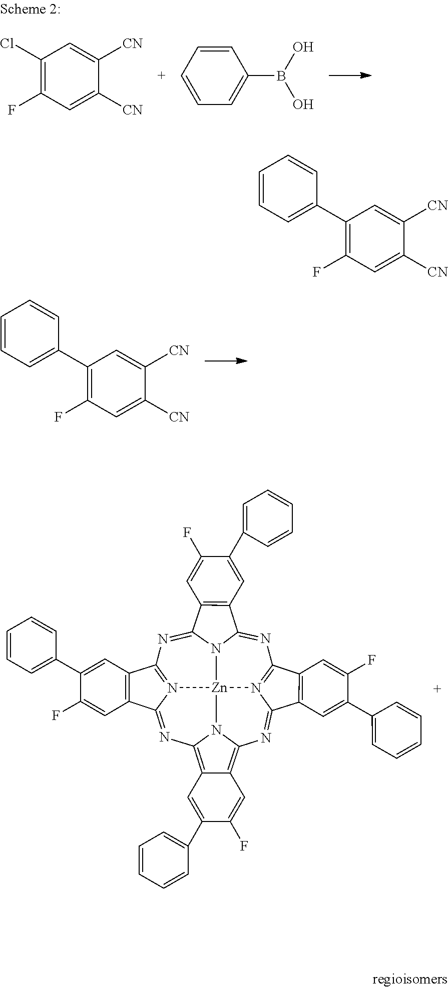

Compounds of the formulae IIb, IIc and IId are commercially available or may be prepared according to known processes.

Some of the compounds of the formulae Ia and Ib are commercially available. The compounds of formula Ia and Ib may be prepared analogously to methods known per se or as described herein, for example starting from an appropriate substituted phthalodinitrile, an appropriate substituted 1,2-naphthalenedicarbonitrile, an appropriate substituted 2,3-naphthalenedicarbonitrile or an appropriate substituted 2,3-anthracenedicarbonitrile and a metal or metal salt. Alternatively they can be prepared starting from a metal halogenide and an appropriate substituted phthalic anhydride, an appropriate substituted 1,2-naphthalenedicarboxylic anhydride, an appropriate substituted 2,3-naphthalenedicarboxylic anhydride or an appropriate substituted 2,3-anthracenedicarboxylic anhydride in the presence of urea.

Compounds of the formula Ia may also be prepared in analogy to processes described in WO 2007/104865.

Organic solar cells generally have a layer structure and generally comprise at least the following layers: anode, photoactive region and cathode. These layers are generally disposed on a substrate customary therefore. The structure of organic solar cells is described, for example, in US 2005/0098726 and US 2005/0224905, which are fully incorporated here by reference.

The invention provides an organic solar cell comprising a substrate with at least one cathode, at least one anode and at least one compound of the formula Ia and/or Ib as defined above as a photoactive material. The organic solar cell according to the invention comprises at least one photoactive region. A photoactive region can comprise two layers that each have a homogeneous composition and form a flat donor-acceptor heterojunction or a mixed layer forming a donor-acceptor bulk heterojunction.

Suitable substrates for organic solar cells are, for example, oxidic materials (such as glass, ceramic, SiO₂, especially quartz, etc.), polymers (e.g. polyvinyl chloride, polyolefins such as polyethylene and polypropylene, polyesters, fluoropolymers, polyamides, polyurethanes, polyalkyl(meth)acrylates, polystyrene and mixtures and composites thereof) and combinations thereof.

Suitable electrodes (cathode, anode) are in principle metals (preferably of groups 8, 9, 10 or 11 of the Periodic Table, e.g. Pt, Au, Ag, Cu, Al, In, Mg, Ca), semiconductors (e.g. doped Si, doped Ge, indium tin oxide (ITO), gallium indium tin oxide (GITO), zinc indium tin oxide (ZITO), etc.), metal alloys (e.g. based on Pt, Au, Ag, Cu, etc., especially Mg/Ag alloys), semiconductor alloys, etc. One of the electrodes used is preferably a material essentially transparent to incident light. This includes, for example, ITO, doped ITO, FTO (fluorine doped tin oxide), AZO (aluminium doped ZnO), ZnO, TiO₂, Ag, Au, Pt. The other electrode used is preferably a material which essentially reflects the incident light. This includes, for example, metal films, for example of Al, Ag, Au, In, Mg, Mg/Al, Ca, etc.

For its part, the photoactive region comprises at least one or consists of at least one layer which comprises, as an organic semiconductor material, at least one compound of the formulae Ia and/or Ib as defined above. In addition to the photoactive region, there may be one or more further layers. These include, for example,
layers with electron-conducting properties (electron transport layer, ETL)
layers which comprise a hole-conducting material (hole transport layer, HTL) which need not absorb,
exciton- and hole-blocking layers (e.g. EBLs) which should not absorb, and
multiplication layers.

Suitable exciton- and hole-blocking layers are described, for example, in U.S. Pat. No. 6,451,415.

Suitable materials for exciton blocker layers are, for example, bathocuproin (BCP), 4,4′,4″-tris[3-methylphenyl-N-phenylamino]triphenylamine (m-MTDATA) or polyethylenedioxy-thiophene (PEDOT).

The solar cells according to the invention comprise at least one photoactive donor-acceptor heterojunction. Upon optical excitation of an organic material, excitons are generated. For photocurrent to occur, the electron-hole pair has to be separated, typically at a donor-acceptor interface between two dissimilar contacting materials. At such an interface, the donor material forms a heterojunction with an acceptor material. If the charges do not separate, they can recombine in a geminate recombination process, also known as quenching, either radiatively, by the emission of light of a lower energy than the incident light, or non-radiatively, by the production of heat. Either of these outcomes is undesirable. When at least one compound of the formulae Ia and/or Ib is used as the charge generating (donor) as well as HTM (hole transport material), and/or the corresponding electron accepting ETM (electron transport material) must be selected such that, after excitation of the compounds, a rapid electron transfer to the ETM takes place. Suitable ETMs are, for example, C60 and other fullerenes, perylene-3,4;9,10-bis(dicarboximides) (PTCDIs), etc. (see in the following).

In a first embodiment, the heterojunction may have a flat (smooth) configuration (cf. Two layer organic photovoltaic cell, C. W. Tang, Appl. Phys. Lett., 48 (2), 183-185 (1986) or N. Karl, A. Bauer, J. Holzäpfel, J. Marktanner, M. Möbus, F. Stölzle, Mol. Cryst. Liq. Cryst., 252, 243-258 (1994).).

In a second, preferred embodiment, the heterojunction may be implemented as a mixed (bulk) heterojunction or interpenetrating donor-acceptor network. Organic photovoltaic cells with a bulk heterojunction are e.g. described by C. J. Brabec, N. S. Sariciftci, J. C. Hummelen in Adv. Funct. Mater., 11 (1), 15 (2001) or by J. Xue, B. P. Rand, S. Uchida and S. R. Forrest in J. Appl. Phys. 98, 124903 (2005). Bulk heterojunctions are discussed in details below.

The compounds of the formula Ia and/or Ib can be used as a photoactive material in solar cells with MiM, pin, pn, Mip or Min structure (M=metal, p=p-doped organic or inorganic semiconductor, n=n-doped organic or inorganic semiconductor, i=intrinsically conductive system of organic layers; cf., for example, J. Drechsel et al., Org. Electron., 5 (4), 175 (2004) or Maennig et al., Appl. Phys. A 79, 1-14 (2004)).

The compounds of the formula Ia and/or Ib can also be used as a photoactive material in tandem cells. Suitable tandem cells are described e.g. by P. Peumans, A. Yakimov, S. R. Forrest in J. Appl. Phys, 93 (7), 3693-3723 (2003) (cf. U.S. Pat. No. 4,461,922, U.S. Pat. No. 6,198,091 and U.S. Pat. No. 6,198,092) and are discussed in details below.

The compounds of the formula Ia and/or Ib can also be used as a photoactive material in tandem cells composed of two or more MiM, pin, Mip or Min diodes stacked on one another (cf. patent application DE 103 13 232.5) (J. Drechsel et al., Thin Solid Films, 451452, 515-517 (2004)).

The layer thicknesses of the M, n, i and p layers are typically from 10 to 1000 nm, preferably from 10 to 400 nm. Thin layers can be produced by vapor deposition under reduced pressure or in inert gas atmosphere, by laser ablation or by solution- or dispersion-processible methods such as spin-coating, knife-coating, casting methods, spraying, dip-coating or printing (e.g. inkjet, flexographic, offset, gravure; intaglio, nanoimprinting).

In order to improve efficiency of an organic solar cell the average distance an exciton must diffuse from its generation to its dissociation site (donor-acceptor interface) can be reduced in an interpenetrating network of the donor and acceptor materials. A preferred morphology of a bulk-heterojunction is characterized by a great donor-acceptor interface area and continuous carrier conducting pathways to the opposing electrodes.

Bulk heterojunctions may be produced by a gas phase deposition process (physical vapor deposition, PVD). Suitable methods are described in US 2005/0227406, to which reference is made here. To this end, typically a compound of formulae Ia and/or Ib as electron donor and at least one electron acceptor material may be subjected to a vapor phase deposition by cosublimation. PVD processes are performed under high-vacuum conditions and comprise the following steps: evaporation, transport, deposition. The deposition is effected preferably at a pressure range from about 10⁻² mbar to 10⁻⁷ mbar, e.g. from 10⁻⁵ to 10⁻⁷ mbar. The deposition rate is preferably in a range from 0.01 to 10 nm/s. The deposition rate of the metal top contact is preferably in a range from 0.01 to 10 nm/s. The deposition can be effected under an inert atmosphere, for example, under nitrogen, argon or helium. The temperature of the substrate in the deposition is preferably within a range from about −100 to 300° C., more preferably from −50 to 250° C.

The other layers of the solar cell can be produced by known methods. These include vapor deposition under reduced pressure or in inert gas atmosphere, by laser ablation or by solution- or dispersion-processible methods such as spin-coating, knife-coating, casting methods, spraying, dip-coating or printing (e.g. inkjet, flexographic, offset, gravure; intaglio, nanoimprinting). The complete solar cell is preferably produced by a gas phase deposition process.

The photoactive region (homogeneous layers or mixed layer) can be subjected to a thermal treatment directly after its preparation or after the preparation of other layers being part of the solar cell. Annealing may improve the morphology of the photoactive region. The temperature is preferably in the range of from 60 to 300° C. and the processing time ranges from 1 minute to 3 hours. In addition or alternatively to a thermal treatment, the photoactive region may be subjected to a treatment using a solvent-containing gas. According to a suitable embodiment saturated solvent vapors in air at ambient temperature are used. Suitable solvents are toluene, xylene, chlorobenzene, trichloromethane, dichloromethane, N-methylpyrrolidone, N,N-dimethylformamide, ethyl acetate and mixtures thereof. The processing time usually ranges from 1 minute to 3 hours.

According to a preferred embodiment of the invention, the solar cell according to the present invention is a flat-heterojunction single cell having a normal structure.

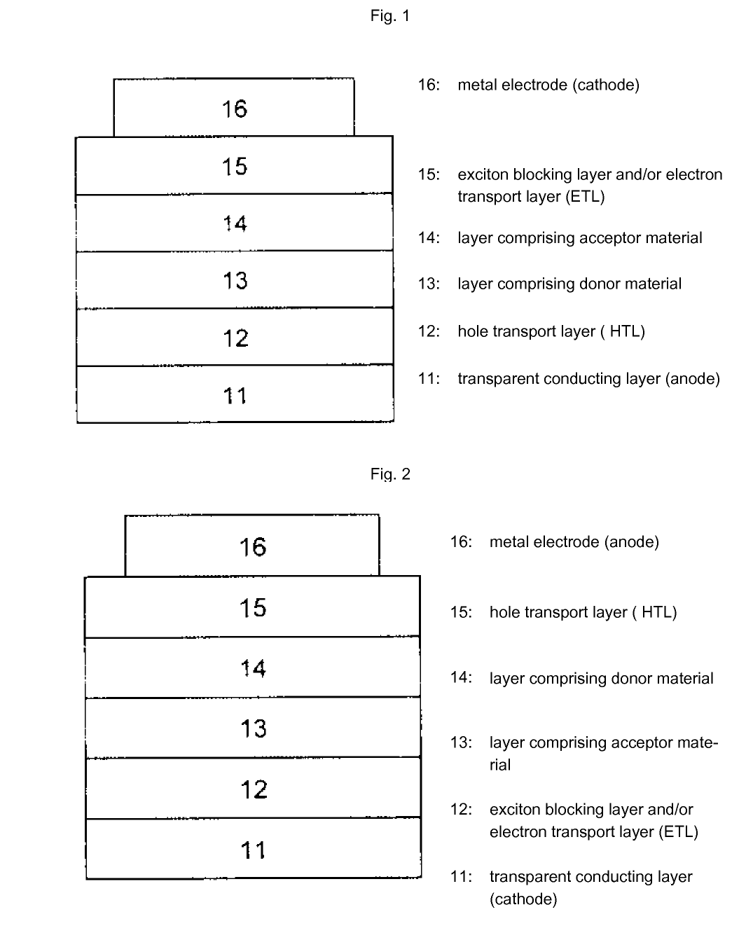

FIG. 1 illustrates a solar cell with normal structure according to the present invention. According to a specific embodiment the cell has the following structure:
a transparent conducting layer (anode) (11)
hole transport layer (HTL) (12)
layer comprising a donor material (13)
layer comprising an acceptor material (14)
exciton blocking layer and/or electron transport layer (15)
electrode (back electrode, cathode)(16)

Preferably, the donor material comprises or consist of a compound of the formulae Ia or Ib. Preferably the acceptor material comprises or consist of a fullerene, more preferably C60 or PCBM ([6,6]-phenyl-C61-butyric acid methyl ester). Likewise preference is given to a cell, comprising or consisting of a compound of formula Ia or Ib as donor material and a rylene, especially 1,6,7,12-tetrachloroperylene-3,4:9,10-tetracarboximide, as acceptor material. In particular, the compounds of formula Ib are selected from ortho-tetraphenyl zinc phthalocyanine, ortho-tetraphenoxy zinc phthalocyanine, ortho-tetraphenoxy copper phthalocyanine, ortho-tetranaphthyl zinc phthalocyanine, ortho-tetra(4-tert-butylphenyl)zinc phthalocyanine, ortho-tetra(2′,5′-dichlorphenyl)zinc phthalocyanine, ortho-tetra(thiophen-2-yl)zinc phthalocyanine, ortho-tetra(thiophen-2-yl)copper phthalocyanine, ortho-tetra(thiophen-3-yl)zinc phthalocyanine and ortho-tetra(2-benzo[b]thienyl)zinc phthalocyanine (examples for flat cell architecture with η≧1). HTL and ETL can be either undoped or doped. Suitable dopants are discussed below.

The transparent conducting layer (11) comprises a carrier substrate such as glass or a polymer (e.g. polyethylene terephthalate) and a transparent conducting material as anode. Suitable anode materials are the aforementioned materials that are essentially transparent to incident light, for example, ITO, doped ITO, FTO, ZnO, AZO, etc. The anode material may be subjected to a surface treatment, e.g. with UV light, ozone, oxygen plasma, Br₂, etc. The transparent conducting layer (11) should be thin enough to ensure minimal light absorption, but thick enough to ensure good lateral charge transport through the layer. The layer thickness of the transparent conducting layer is preferably in the range of from 20 to 200 nm.

The solar cell with normal structure according to FIG. 1 optionally comprises a hole transport layer (12). This layer comprises at least one hole transport material (HTM). Layer 12 can be a single layer of essentially homogeneous composition or can comprise two or more sublayers. Suitable hole transport materials and the corresponding hole transport layer (HTL) are characterized by a high work function or ionization energy. The ionization energy is preferably at least 5.0 eV, more preferably at least 5.5 eV. The HTM can be at least one organic compound, such as poly(3,4-ethylenedioxythiophene) doped with poly(styrenesulfonate)(PEDOT-PSS), Ir-DPBIC (Tris-N,N′-Diphenylbenzimidazol-2-yliden-iriddium(III)), N,N′-diphenyl-N,N′-bis(3-methylphenyl)-1,1′-diphenyl-4,4′-diamine (α-NPD), 2,2′,7,7′-tetrakis(N,N-di-p-methoxyphenylamine)-9,9′-spirobifluorene (spiro-MeOTAD), etc. The HTM can also be at least one inorganic compound, such as WO₃, MoO₃, etc. The thickness of layer (12) is preferably in a range of from 0 to 1 μm, more preferably from 0 to 100 nm. Organic compounds employed as HTM can be doped with p-dopant, which has LUMO similar or deeper than the HOMO of the HTM, such as 2,3,5,6-tetrafluoro-7,7,8,8-tetracyano-quino-dimethane (F₄TCNQ), WO₃, MoO₃, etc.

Layer 13 comprises at least one phthalocyanine, selected from compounds of the formula Ia, compounds of the formula Ib and mixtures thereof. The thickness of the layer should be thick enough to absorb as much light as possible, but still thin enough to extract charges efficiently. The thickness of layer (13) is preferably in a range of from 5 nm to 1 μm, more preferably from 5 to 80 nm.

Layer (14) comprises at least one acceptor material. Suitable and preferred acceptor materials are mentioned in the following. The thickness of the layer should be thick enough to absorb as much light as much as possible, but still thin enough to extract charges efficiently. The thickness of layer (14) is preferably in a range of from 5 nm to 1 μm, more preferably 5 to 80 nm.

The solar cell with normal structure according to FIG. 1 optionally comprises an exciton blocking layer and/or electron transport layer (15). The exciton blocking layer should have a larger optical gap than the materials of layer (14) to reflect the excitons and still enable good electron transport through the layer. Preferably layer (15) comprises at least one compound selected from 2,9-dimethyl-4,7-diphenyl-1,10-phenanthroline (BCP), (4,7-diphenyl-1,10-phenanthroline) Bphen, 1,3-bis[2-(2,2′-bupyridine-6-yl)1,3,4-oxadizo-5-yl]benzene (BPY-OXD), zinc oxide, titanium oxide, etc. Organic compounds employed in layer (15) can be doped with an n-dopant, which has HOMO similar or smaller than the LUMO of the electron-transport layer, such as Cs₂CO₃, pyronin B (PyB), rhodamine B, cobaltocene, etc. The thickness of layer (15) is preferably in a range of from 0 to 500 nm, more preferably from 0 to 60 nm.

Layer (16) is the cathode and comprises at least one material with low work function such as Ag, Al, Ca, Mg or a mixture thereof. The thickness of layer (16) is preferably in a range of from 10 nm to 10 μm, e.g. 10 nm to 60 nm.

According to further preferred embodiment of the invention, the solar cell is a flat-heterojunction single cell having an inverse structure. FIG. 2 illustrates a solar cell with inverse structure according to the present invention.

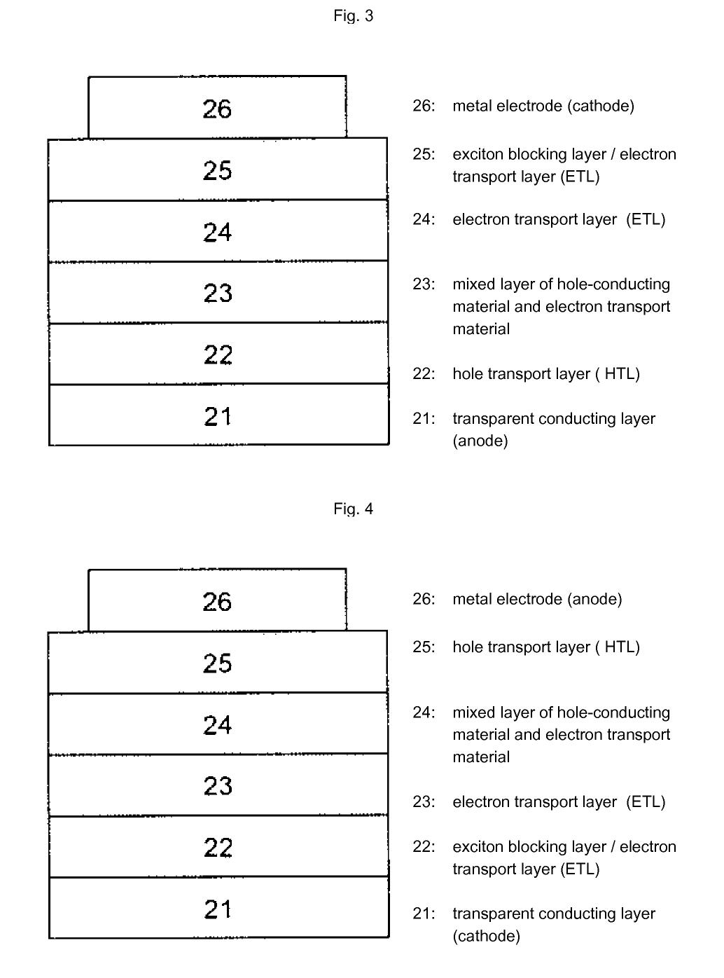

According to a further preferred embodiment of the invention, the solar cell according to the present invention is a bulk-heterojunction single cell having a normal structure. FIG. 3 illustrates a solar cell with normal structure according to the present invention.

According to a specific embodiment the cell has the following structure:
a transparent conducting layer (anode) (21)
hole transport layer (HTL) (22)
mixed layer of a hole-conducting material and electron transport material in form of a bulk heterojunction (23)
electron transport layer (ETL) (24)
exciton blocking layer/electron transport layer (25)
electrode (back electrode, cathode)

Preferably, the mixed layer comprises a compound of formulae Ia or Ib or a mixture of thereof as the donor material and a fullerene, especially C60 or PCBM ([6,6]-phenyl-C61-butyric acid methyl ester), as the acceptor material. Likewise preference is given to those mixed layers consisting of a compound of formulae Ia or Ib or a mixture thereof and a rylene, especially 1,6,7,12-tetrachloroperylene-3,4:9,10-tetracarboximide.

In particular, the compounds of formula Ib are selected from ortho-tetraphenyl zinc phthalocyanine, ortho-tetraphenoxy zinc phthalocyanine, ortho-tetraphenoxy copper phthalocyanine, ortho-tetra(4-tert-butylphenyl)zinc phthalocyanine, ortho-tetra(thiophen-2-yl)zinc phthalocyanine, ortho-tetra(thiophen-2-yl)copper phthalocyanine, ortho-(2-benzo[b]thienyl)zinc phthalocyanine, (examples for BHJ cell architecture with η≧1). HTL and ETL can be either undoped or doped. Suitable dopants are discussed below.

With regard to layer 21, reference is made to layer 11 mentioned before.

With regard to layer 22, reference is made to layer 12 mentioned before.

Layer 23 is a mixed layer of at least one phthalocyanine of formulae Ia or Ib or a mixture thereof as the donor material and an acceptor material. The mixed layer can be prepared by co-evaporation as mentioned before or by solution processing using common solvents. The mixed layer comprises preferably from 10 to 90 wt %, more preferably from 20 to 80 wt %, of at least one phthalocyanine of formulae Ia or Ib or mixture thereof based on the total weight of the mixed layer. The mixed layer comprises preferably from 10 to 90 wt %, more preferably from 20 to 80 wt %, of at least one acceptor material based on the total weight of the mixed layer. The thickness of layer (23) should be thick enough to absorb as much light as possible, but still thin enough to extract charges efficiently. The thickness of layer (23) is preferably in a range of from 5 nm to 1 μm, more preferably 5 to 200 nm, specially from 5 to 80 nm.

The bulk-heterojunction solar cell with normal structure according to FIG. 3 comprises an electron transport layer (24). This layer comprises at least one electron transport material (ETM). Layer 24 can be a single layer of essentially homogeneous composition or can comprise two or more sublayers. Suitable electron transport materials and the corresponding electron transport layer (ETL) are characterized by a low work function or ionization energy. The ionization energy is preferably less than 3.5 eV. The ETM can be at least one organic compound, such as C60, BCP, Bphen, BPY-OXD. The ETM also can be at least one inorganic compound, such as zinc oxide, titanium oxide etc. Organic compounds employed in layer (24) can be doped with an n-dopant, which has HOMO similar or smaller than the LUMO of the electron-transport layer, such as Cs₂CO₃, pyronin B (PyB), rhodamine B, cobaltocene, etc. The thickness of layer (24) is preferably in a range of from 0 to 1 μm, more preferably from 0 to 60 nm.

With regard to layer 25, reference is made to layer 15 mentioned before.

With regard to layer 26, reference is made to layer 16 mentioned before.

The organic solar cell with bulk heterojunctions may be produced by a gas phase deposition process as mentioned before. With regard to the deposition rate, the temperature of the substrate in the deposition and thermal treatment (annealing) reference is made to the disclosure above.

According to a further preferred embodiment of the invention, the solar cell according to the present invention is a bulk-heterojunction single cell having an inverse structure. FIG. 4 illustrates a solar cell with inverse structure according to the present invention.

According to further preferred embodiment of the invention, the solar cell according to the present invention is a tandem cell.

A tandem cell comprises two or more than two, e.g. 3, 4, 5, etc., subcells. A single subcell, some of the subcells or all subcells may comprise a donor-acceptor heterojunction based on a compound of formulae Ia and/or Ib. Each donor-acceptor heterojunction can in form of a flat heterojunction or a bulk heterojunction. In a preferred embodiment, at least one of the donor-acceptor heterojunctions of the tandem cell are in form of a bulk heterojunction.

Preferably, at least one of the subcells comprises a compound of formulae Ia or Ib and at least one fullerene, especially C60 or PCBM. In a further preferred embodiment, at least one of the subcells comprises a compound of formulae Ia or Ib and at least one rylene, especially 1,6,7,12-tetrachloroperylene-3,4:9,10-tetracarboximide. In particular, the compounds of formula Ib are selected from those mentioned before for single cells, dependent if they are employed in a flat heterojunction or a bulk heterojunction.

The subcells forming the tandem cell may be connected in series or parallel. Preference is given to those tandem cells, wherein the subcells are connected in series. Preferably, an additional recombination layer is between the single subcells. Both normal structure and inverse structure can be used as subcell. However, the polarity of all subcells should be in one direction, i.e. all cells have a normal structure or all cells have an inverse structure.

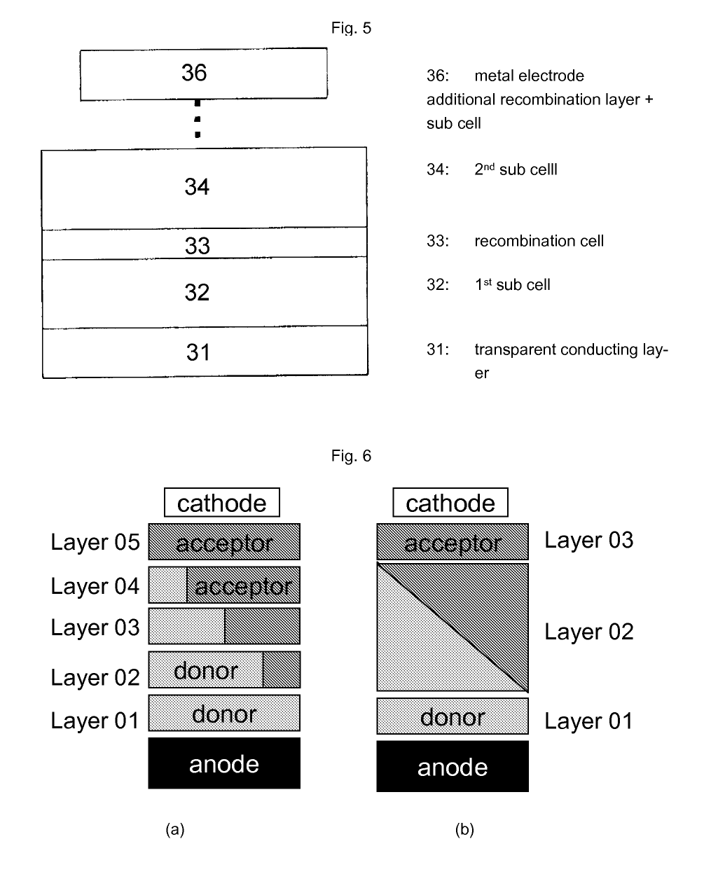

FIG. 5 illustrates a tandem cell according to the present invention. Layer 31 is a transparent conducting layer. Suitable materials are those mentioned herein for the single cells.

With regard to layer 31, reference is made to layers 11 and 21 mentioned before.

Layer 32 and 34 are the individual subcells. Here, subcell refers to functional layers of a single cell, excluding cathode and anode. Reference is made to layers 12 to 15 for cells with flat heterojunction and to layers 22 to 25 for cells with bulk heterojunction.

In one embodiment, all of the subcells can comprise at least one compound of formulae Ia and/or Ib. In a further embodiment, at least one subcell that comprises at least one compound of formulae Ia and/or Ib is combined with at least one subcell based on a different semiconductor material. Thus, C60 can be combined with a phthalocyanine different from those of formulae Ia and Ib, such as zinc phthalocyanine or copper phthalocyanine. Further, C60 can be combined with dibenzotetraphenyl-periflanthene, oligothiophenes such as α,α′-bis(2,2-dicyanovinyl)-quinquethiophene (DCV5T) and the like. The subcells can also be either all of compound of formulae Ia and/or Ib and PCBM ([6,6]-phenyl-C61-butyric acid methyl ester) or a compound of formulae Ia and/or Ib—PCBM cell and another combination of semiconductor material such as PCBM combined with poly(alkylthiophenes) such as poly(3-hexylthiophene).

In all cases, the best case is a combination of materials such a combination that the absorption of each subcell does not overlap too much, but is distributed over the solar spectrum, which in turns contributes to the higher photocurrent. For example, a second subcell with longer wavelength absorption is placed next to a first subcell having a shorter wavelength absorption than the first subcell to increase the absorption range. Preferably, the tandem cell can absorb in the region from 400 to 800 nm. Another subcell that can absorb from 800 nm and on can be placed next to the cell to increase the absorption to near infra red range. For best performance, the subcell with absorption in shorter wavelength is placed closer to the metal top contact than the subcell with the longer wavelength absorption.

Layer 33 is a recombination layer. The recombination layer enables one type of charge produced in one subcell to recombine to the other type of charge generated from adjacent subcells. Small metal clusters such as Ag, Au or combinations of highly doped n- and p-dopant layers can be used. In case of metal clusters, the thickness ranges from 0.5 to 5 nm. In the case of n- and p-dopant layers the thickness ranges from 5 to 40 nm. The recombination layer usually connects an electron transport layer of one subcell with the hole transport layer of the another subcell. In so doing this, further subcells may be combined to a tandem cell.

Layer 36 is the top electrode. The material of the top electrode depends on the polarity direction of the subcells. When the subcells take normal structure, the top metal is preferably made from low work function materials, such as Ag, Mg, Ca or Al. When the subcells take inverse structure, the top metal is preferably made from high work function materials such as Au, Pt, PEDOT-PSS.

In tandem structure connected in series, the overall voltage is the sum of the single subcells. The overall current is limited by the lowest current amongst the single subcells. For this reason, the thickness of each subcell should be re-optimized so that all subcell show similar current.

Examples of various types of donor-acceptor heterojunctions are a donor-acceptor bilayer forming a planar heterojunction or a hybrid planar-mixed heterojunction or a gradient bulk heterojunction or an annealed bulk heterojunction.

The preparation of a hybrid planar-mixed heterojunction is described in Adv. Mater. 17, 66-70 (2005). Coevaporated mixed heterojunction layers are sandwiched between homogenous donor and acceptors materials.

According to a specific embodiment of the invention, the donor-acceptor heterojunction is a gradient bulk heterojunction. The bulk heterojunction layer has a gradual change in donor-acceptor ratio. The cell can have stepwise gradient (FIG. 6 (a)), where layer 01 consists of 100% donor, layer 02 has donor/acceptor ratio >1, layer 03 has donor/acceptor ratio=1, layer 04 has donor/acceptor ratio <1, and layer 05 consists of 100% acceptor. It can also have smooth gradient. (FIG. 6 (b)) where layer 01 consists of 100% donor, layer 02 has decreasing ratio of donor/acceptor as the layer is distanced from the layer 01, and layer 03 consists of 100% acceptor. Different donor-acceptor ratio can be controlled by deposition rate of each material. Such structure can enhance the percolation path of charges.

According to a further specific embodiment of the invention, the donor-acceptor heterojunction is an annealed bulk heterojunction as described for example in Nature 425, 158-162, 2003. The method of fabricating said type of solar cell comprises an annealing step before or after metal deposition. With annealing, donor and acceptor materials can segregate which leads to larger percolation paths.

According to a further specific embodiment of the invention, the solar cells are prepared by organic vapor phase deposition in either a planar or controlled heterojunction architecture. Solar cells of this type are described in Materials, 4, 2005, 37.

According to a further preferred embodiment of the invention the organic solar cell comprises a metallophthalocyanine different from formula Ia and Ib, e.g. copper phthalocyanine, an interlayer of a compound of formula Ia and/or Ib and an electron acceptor, e.g. a fullerene such as C60. Solar cells of this type are described in U.S. patent application Ser. No. 11/486,163. Without wishing to be bound to any theory, the purpose of the interlayer is to push the hole away from the disassociating interface, so that they do not come close together after they are separated from exciton to get lost by recombination. To achieve this, the interlayer has a deeper HOMO (larger ionization potential) than that of the donor, so that the holes drop to the donor immediately after disassociation has taken place. The interlayer should not block excitons from reaching the disassociating interface, and therefore has to have lower optical gap than the donor. The compound used in the interlayer must have absorption at equal or lower energy (longer wavelength) than the electron donor material. The interlayer must be very thin (<4 nm), since the holes in the interlayer must “see” the donor, in order for them to fall to the HOMO of the donor.

Suitable organic solar cells may, as mentioned above, have at least one compound of the formula Ia and/or Ib used in accordance with the invention as an electron donor (p-semiconductor).

In addition to the compounds of the general formulae Ia or Ib, the following semiconductor materials are suitable for use in organic photovoltaics:

Phthalocyanines other than the compounds of the formula Ia and Ib, used in accordance with the invention. These include phthalocyanines which are unhalogenated or which bear up to 16 halogen substituents. These phthalocyanines may be metal-free phthalocyanines or phthalocyanines comprising divalent metals or groups containing metal atoms, especially those of titanyloxy, vanadyloxy, iron, copper, zinc etc. Suitable phthalocyanines are especially copper phthalocyanine, zinc phthalocyanine, metal-free phthalocyanine, copper hexadecachlorophthalocyanine, zinc hexadecachlorophthalocyanine, metal-free hexadecachlorophthalocyanine, copper hexadecafluorophthalocyanine, zinc hexadecafluorophthalocyanine or metal-free hexadecafluorophthalocyanine.

Porphyrins, for example 5, 10,15,20-tetra(3-pyridyl)porphyrin (TpyP); or else tetrabenzoporphyrins, for example metal-free tetrabenzoporphyrin, copper tetrabenzoporphyrin or zinc tetrabenzoporphyrin; especially preferred are tetrabenzoporphyrins which, like the compounds of the formula (I) used in accordance with the invention, are processed as soluble precursors from solution and are converted to the pigmentary photoactive component on the substrate by thermolysis.

Acenes such as anthracene, tetracene, pentacene and substituted acenes. Substituted acenes comprise at least one substituent selected from electron-donating substituents (e.g. alkyl, alkoxy, ester, carboxylate or thioalkoxy), electron-withdrawing substituents (e.g. halogen, nitro or cyano) and combinations thereof. These include 2,9-dialkylpentacenes and 2,10-dialkylpentacenes, 2,10-dialkoxypentacenes, 1,4,8,11-tetraalkoxypentacenes and rubrene (5,6,11,12-tetraphenylnaphthacene). Suitable substituted pentacenes are described in US 2003/0100779 and U.S. Pat. No. 6,864,396. A preferred acene is rubrene (5,6,11,12-tetraphenylnaphthacene).

Liquid-crystalline (LC) materials, for example coronenes such as hexabenzocoronene (HBC-PhC₁₂), coronenediimides, or triphenylenes such as 2,3,6,7,10,11-hexahexylthiotriphenylene (HTT₆), 2,3,6,7,10,11-hexakis(4-n-nonylphenyl)-triphenylene (PTP₉) or 2,3,6,7,10,11-hexakis(undecyloxy)triphenylene (HAT₁₁). Particular preference is given to liquid-crystalline materials which are discotic. Suitable liquid-crystalline (LC) materials also include liquid crystalline phthalocyanines. These include phthalocyanines which bear C₆-C₁₈ alkyl, C₆-C₁₈ alkoxy and C₆-C₁₈ alkoxycarbonyl radicals, wherein C₆-C₁₈ alkyl may be interrupted by oxygen. Suitable liquid crystalline phthalocyanines are described in Chem. Soc. Rev. 2007, 36, 1902-1929.

Thiophenes, oligothiophenes and substituted derivatives thereof. Suitable oligothiophenes are quaterthiophenes, quinquethiophenes, sexithiophenes, α,ω-di(C₁-C₈)alkyloligothiophenes such as α,ω-dihexylquaterthiophenes, α,ω-dihexylquinquethiophenes and α,ω-dihexylsexithiophenes, poly(alkylthiophenes) such as poly(3-hexylthiophene), bis(dithienothiophenes), anthradithiophenes and dialkylanthradithiophenes such as dihexylanthradithiophene, phenylene-thiophene (P-T) oligomers and derivatives thereof, especially α,ω-alkyl-substituted phenylene-thiophene oligomers.

Also suitable are compounds of the α,α′-bis(2,2-dicyanovinyl)quinquethiophene (DCV5T) type, (3-(4-octylphenyl)-2,2′-bithiophene) (PTOPT), poly(3-(4′-(1,4,7-trioxaoctyl)phenyl)thiophene (PEOPT), poly(3-(2′-methoxy-5′-octylphenyl)thiophene) (POMeOPT), poly(3-octylthiophene) (P₃OT), poly(pyridopyrazinevinylene)-polythiophene blends such as EHH-PpyPz, PTPTB copolymers, BBL, F₈BT, PFMO; see Brabec C., Adv. Mater., 2996, 18, 2884, (PCPDTBT) poly[2,6-(4,4-bis(2-ethylhexyl)-4H-cyclopenta[2,1-b;3,4-b′]-dithiophene)-4,7-(2,1,3-benzothiadiazole).

Poly-phenylene-ethynylene (PPE), paraphenylenevinylene and paraphenylenevinylene-comprising oligomers and polymers, for example polyparaphenylenevinylene, MEH-PPV (poly(2-methoxy-5-(2′-ethylhexyloxy)-1,4-phenylenevinylene)), MDMO-PPV (poly(2-methoxy-5-(3′,7′-dimethyloctyloxy)-1,4-phenylenevinylene)), PPV, CN-PPV (with various alkoxy derivatives).

Phenyleneethynylene/phenylenevinylene hybrid polymers (PPE-PPV).

Polyfluorenes and alternating polyfluorene copolymers, for example with 4,7-dithien-2′-yl-2,1,3-benzothiadiazole. Also suitable are poly(9,9′-dioctylfluorene-co-benzothiadiazole) (F₈BT), poly(9,9′-dioctylfluorene-co-bis(N,N′-(4-butylphenyl))-bis(N,N′-phenyl)-1,4-phenylenediamine (PFB).

Polycarbazoles, i.e. carbazole-comprising oligomers and polymers.

Polyanilines, i.e. aniline-comprising oligomers and polymers.

Triarylamines, polytriarylamines, polycyclopentadienes, polypyrroles, polyfurans, polysiloles, polyphospholes, TPD, CBP, spiro-MeOTAD.

Rylenes. In the context of this application, the term “rylenes” refers to compounds having a molecular structure of naphthalene units linked in the peri position. According to the number of naphthalene units, they may, for example, be perylenes (n=2), terrylenes (n=3), quaterrylenes (n=4) or higher rylenes. Accordingly, they may be perylenes, terrylenes or quaterrylenes of the following formula

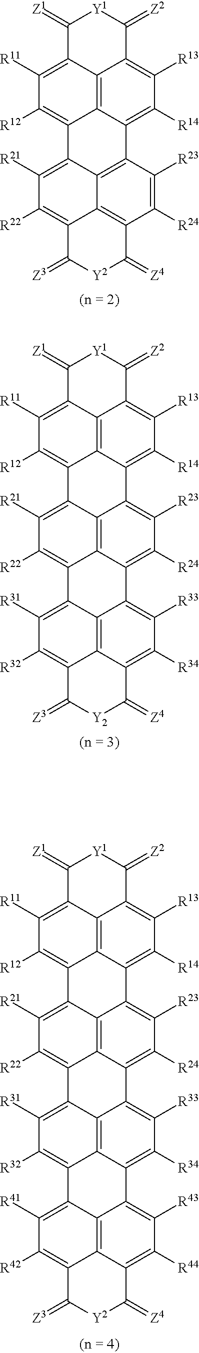

in which
the Rⁿ¹, Rⁿ², Rⁿ³ and Rⁿ⁴ radicals where n is from 1 to 4 may each independently be hydrogen, halogen or groups other than halogen,
Y¹ is O or NR^{a}, where R^{a} is hydrogen or an organyl radical,
Y² is O or NR^{b}, where R^{b} is hydrogen or an organyl radical,
Z¹, Z², Z³ and Z⁴ are each O,
where, in the case that Y¹ is NR^{a}, one of the Z¹ and Z² radicals may also be NR^{c}, where the R^{a} and R^{c} radicals together are a bridging group having from 2 to 5 atoms between the flanking bonds, and
where, in the case that Y² is NR^{b}, one of the Z³ and Z⁴ radicals may also be NR^{d}, where the R^{b} and R^{d} radicals together are a bridging group having from 2 to 5 atoms between the flanking bonds.

Suitable rylenes are, for example, described in WO 2007/074137, WO 2007/093643 and WO 2007/116001, to which reference is made here.

Fullerenes and fullerene derivatives, especially C60 and derivatives thereof such as PCBM (=[6,6]-phenyl-C60-butyric acid methyl ester) (see below).

In the context of this application, the term “fullerene” refers to a material which is composed of carbon and has a regular, three-dimensional network of fused carbon rings. These may have spherical, cylindrical, ovoid, flattened or angular structures. Suitable fullerenes are, for example, C60, C70, C76, C80, C82, C84, C86, C90, C96, C120, single-walled carbon nanotubes (SWNT) and multi-walled carbon nanotubes (MWNT). Examples of fullerene derivatives are phenyl-C₆₁-butyric acid methyl ester, phenyl-C₇₁-butyric acid methyl ester ([71]PCBM), phenyl-C₈₄-butyric acid methyl ester ([84]PCBM), phenyl-C₆₁-butyric acid butyl ester ([60]PCBB), phenyl-C₆₁-butyric acid octyl ester ([60]PCBO) and thienyl-C61-butyric acid methyl ester ([60]ThCBM). Particular preference is given to using C60. Also suitable are fullerene derivatives such as PCBM (=[6,6]-phenyl-C61-butyric acid methyl ester).

In the organic solar cells of the invention, particular preference is given to using a combination of semiconductor materials which comprises at least one compound of the formula Ib and C60. In the organic solar cells of the invention, particular preference is also given to using a combination of semiconductor materials which comprises at least one compound of the formula Ib and PCBM.

In a specific embodiment, the phthalocyanine is an isomeric mixture of phthalocyanines of the following formula Ib-oPc

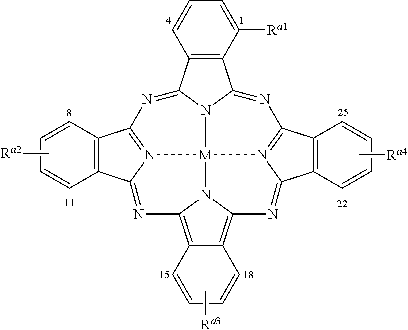

in which each isomer has a first substituent R^{a1} in the 1 position, a second substituent R^{a2} in the 8 or 11 position, a third substituent R^{a3} in the 15 or 18 position and a fourth substituent R^{a} in the 22 or 25 position. M is preferably Zn (II), Cu(II), Al(III)Cl, Al(III)F, In(III)F or In(III)Cl, in particular Zn(II) or Cu(II).

Particularly preferred is a combination of ortho-tetraphenyl zinc phthalocyanine and C60.

Particularly preferred is also a combination of ortho-tetraphenyl copper phthalocyanine and C60.

Particularly preferred is also a combination of ortho-tetraphenoxy zinc phthalocyanine and C60.

Particularly preferred is also a combination of ortho-tetraphenoxy copper phthalocyanine and C60.

Particularly preferred is also a combination of ortho-tetranaphthyl zinc phthalocyanine and C60.

Particularly preferred is also a combination of ortho-tetranaphthyl copper phthalocyanine and C60.

Particularly preferred is also a combination of ortho-tetra(4-tert-butylphenyl)zinc phthalocyanine and C60.

Particularly preferred is also a combination of ortho-tetra(4-tert-butylphenyl)copper phthalocyanine and C60.

Particularly preferred is also a combination of ortho-tetra(2′,5′-dichlorophenyl)zinc phthalocyanine and C60.

Particularly preferred is also a combination of ortho-tetra(2′,5′-dichlorophenyl)copper phthalocyanine and C60.

Particularly preferred is also a combination of ortho-tetra(thiophen-2-yl)zinc phthalocyanine and C60.

Particularly preferred is also a combination of ortho-tetra(thiophen-2-yl)copper phthalocyanine and C60.

Particularly preferred is also a combination of ortho-tetra(thiophen-3-yl)zinc phthalocyanine and C60.

Particularly preferred is also a combination of ortho-tetra(thiophen-3-yl)copper phthalocyanine and C60.

Particularly preferred is also a combination of ortho-tetra(2-benzo[b]thienyl)zinc phthalocyanine and C60.

Particularly preferred is also a combination of ortho-tetra(2-benzo[b]thienyl)copper phthalocyanine and C60.

Particularly preferred is also a combination of ortho-tetraphenyl zinc phthalocyanine and PCBM.

Particularly preferred is also a combination of ortho-tetraphenyl copper phthalocyanine and PCBM.

Particularly preferred is also a combination of ortho-tetraphenoxy zinc phthalocyanine and PCBM.

Particularly preferred is also a combination of ortho-tetraphenoxy copper phthalocyanine and PCBM.

Particularly preferred is also a combination of ortho-tetranaphthyl zinc phthalocyanine and PCBM.

Particularly preferred is also a combination of ortho-tetranaphthyl copper phthalocyanine and PCBM.

Particularly preferred is also a combination of ortho-tetra(4-tert-butylphenyl)zinc phthalocyanine and PCBM.

Particularly preferred is also a combination of ortho-tetra(4-tert-butylphenyl)copper phthalocyanine and PCBM.

Particularly preferred is also a combination of ortho-tetra(2′,5′-dichlorophenyl)zinc phthalocyanine and PCBM.

Particularly preferred is also a combination of ortho-tetra(2′,5′-dichlorophenyl)copper phthalocyanine and PCBM.

Particularly preferred is also a combination of ortho-tetra(thiophen-2-yl)zinc phthalocyanine and PCBM.

Particularly preferred is also a combination of ortho-tetra(thiophen-2-yl)copper phthalocyanine and PCBM.

Particularly preferred is also a combination of ortho-tetra(thiophen-3-yl)zinc phthalocyanine and PCBM.

Particularly preferred is also a combination of ortho-tetra(thiophen-3-yl)copper phthalocyanine and PCBM.

Particularly preferred is also a combination of ortho-tetra(2-benzo[b]thienyl)zinc phthalocyanine and PCBM.

Particularly preferred is also a combination of ortho-tetra(2-benzo[b]thienyl)copper phthalocyanine and PCBM.

Particularly preferred is also a combination of ortho-tetraphenyl zinc phthalocyanine and 1,6,7,12-tetrachloroperylene-3,4:9,10-tetracarboximide.

Particularly preferred is also a combination of ortho-tetraphenyl copper phthalocyanine and 1,6,7,12-tetrachloroperylene-3,4:9,10-tetracarboximide.

Particularly preferred is also a combination of ortho-tetraphenoxy zinc phthalocyanine and 1,6,7,12-tetrachloroperylene-3,4:9,10-tetracarboximide.

Particularly preferred is also a combination of ortho-tetraphenoxy copper phthalocyanine and 1,6,7,12-tetrachloroperylene-3,4:9,10-tetracarboximide.

Particularly preferred is also a combination of ortho-tetranaphthyl zinc phthalocyanine and 1,6,7,12-tetrachloroperylene-3,4:9,10-tetracarboximide.

Particularly preferred is also a combination of ortho-tetranaphthyl copper phthalocyanine and 1,6,7,12-tetrachloroperylene-3,4:9,10-tetracarboximide.

Particularly preferred is also a combination of ortho-tetra(4-tert-butylphenyl)zinc phthalocyanine and 1,6,7,12-tetrachloroperylene-3,4:9,10-tetracarboximide.

Particularly preferred is also a combination of ortho-tetra(4-tert-butylphenyl)copper phthalocyanine and 1,6,7,12-tetrachloroperylene-3,4:9,10-tetracarboximide.

Particularly preferred is also a combination of ortho-tetra(2′,5′-dichlorophenyl)zinc phthalocyanine and 1,6,7,12-tetrachloroperylene-3,4:9,10-tetracarboximide.

Particularly preferred is a combination of ortho-tetra(2′,5′-dichlorophenyl)copper phthalocyanine and 1,6,7,12-tetrachloroperylene-3,4:9,10-tetracarboximide.

Particularly preferred is also a combination of ortho-tetra(thiophen-2-yl)zinc phthalocyanine and 1,6,7,12-tetrachloroperylene-3,4:9,10-tetracarboximide.

Particularly preferred is also a combination of ortho-tetra(thiophen-2-yl)copper phthalocyanine and 1,6,7,12-tetrachloroperylene-3,4:9,10-tetracarboximide.

Particularly preferred is also a combination of ortho-tetra(thiophen-3-yl)zinc phthalocyanine and 1,6,7,12-tetrachloroperylene-3,4:9,10-tetracarboximide.

Particularly preferred is also a combination of ortho-tetra(thiophen-3-yl)copper phthalocyanine and 1,6,7,12-tetrachloroperylene-3,4:9,10-tetracarboximide.

Particularly preferred is also a combination of ortho-tetra(2-benzo[b]thienyl)zinc phthalocyanine and 1,6,7,12-tetrachloroperylene-3,4:9,10-tetracarboximide.

Particularly preferred is also a combination of ortho-tetra(2-benzo[b]thienyl)copper phthalocyanine and 1,6,7,12-tetrachloroperylene-3,4:9,10-tetracarboximide.

According to a preferred embodiment of the invention, the solar cell according to the present invention is a flat-heterojunction solar cell having the following structure:

### ITO

compound of formula Ia and/or Ib

### C60

BPhen (=4,7-diphenyl-1,10-phenanthroline)

### Ag

According to a preferred embodiment of the invention, the solar cell according to the present invention is a flat-heterojunction solar cell having the following structure:

### ITO

compound of formula Ib and C60, weight ratio 2:1 to 1:2

### C60

### BPhen

### Ag

All aforementioned semiconductor materials may also be doped. The conductivity of such semiconductor material may be enhanced through the use of chemical doping techniques using various electron acceptor and/or electron donor dopants. In a specific embodiment, the compound of the formula Ia and/or Ib and/or (if present) a different semiconductor material is thus used in the inventive organic solar cells in combination with at least one dopant. The organic material may be doped with an n-dopant having a HOMO energy level close to or higher in energy to the LUMO energy level of the electron conducting material. The organic material may be doped with a p-dopant having a LUMO energy level close to or lower in energy to the HOMO energy level of the hole conducting material. In other words, in the case of n-doping, an electron is released from the dopant acting as donor, whereas in the case of p-doping, the dopant acting as acceptor absorbs an electron.

Suitable dopants for use of the compounds Ia and Ib as n-semiconductors are Cs₂CO₃, LiF, pyronin B (PyB), rhodamine derivatives, especially rhodamine B, cobaltocene, etc, in particular pyronin B and rhodamine derivatives.

Examples of suitable dopants for p-semiconductors are WO₃, MoO₃, 2,3,5,6-tetrafluoro-7,7,8,8-tetracyanoquinodimethane (F₄-TCNQ), 3,6-difluoro-2,5,7,7,8,8-hexacyanoquinodimethane, dichlorodicyanoquinone (DDQ) or tetracyanoquinodimethane (TCNQ), especially 3,6-difluoro-2,5,7,7,8,8-hexacyanoquinodimethane.

Typically, the dopants may be employed in concentrations of up to about 10 mole percent based on the semiconductor material to be doped, preferably up to 5 mole percent based on the semiconductor material to be doped. In particular, a dopant is employed in an amount of 0.1 to 3 mole percent, based on the semiconductor material to be doped.

### EXAMPLES

The phthalocyanine compounds referred to as ortho-phthalocyanine compounds denote the single compound as well as a mixture of regioisomers as defined above. The phthalocyanine compounds referred to as meta-phthalocyanine compounds denote the single compound as well as a mixture of regioisomers as defined above.

### I. Preparation Examples

### Example 1

### ortho-Tetraphenyl zincphthalocyanine

### 1.1 3-Chlorophthalonitrile

3-Fluorophthalonitrile (30 mmol, 4.38 g) and lithium chloride (2.54 g, 60 mmol) were refluxed at 250° C. in anhydrous N-methylpyrrolidone (NMP) for 5 hours. The resulting brown solution was cooled and poured on crushed ice and the resulting precipitate was washed well with water and filtered. The solid obtained was air-dried for 24 h and dried under vacuum at 60° C. for 15 h to give 4.55 g (93.6%) of the title compound. The compound was used without any further purification in the next step.

¹H-NMR (CDCl₃, 400 MHz, ppm): δ 7.79 (dd, 1H), 7.73 (dd, 1H), 7.68 (t, 1H);

¹³C-NMR (CDCl₃, 400 MHz, ppm): δ 139.15, 134.40, 134.08, 131.84, 118.15, 116.79, 114.77, 113.02.

### 1.2 Biphenyl-2,3-dicarbonitrile (3-Phenylphthalonitrile)

3-Chlorophthalonitrile (20 mmol, 3.24 g), phenyl boronic acid (25 mmol, 2.92 g), bis(tritert-butylphosphine)palladium(0) (Pd[P(tBu)₃]₂) (0.14 mmol, 0.072 g), and CsF (40 mmol, 6.04 g) were added to a dry 100 mL two-neck flask in an argon atmosphere and dried under vacuum for few minutes and kept under argon atmosphere. 50 mL of dry dioxane were then added to the flask and stirred at room temperature. To the stirred solution 2 mL of degassed water was added through a syringe. After completion of the addition the reaction mixture was stirred at 85° C. for 17 hours. Then, the reaction mixture was cooled to room temperature and diluted with dichloromethane and filtered through celite. The filtrate was concentrated and purified by column chromatography using hexane/toluene (3:2) as eluents. The title compound was the first eluate from the column. After concentration, 3.3 g (80.9%) of the title compounds were obtained as colorless solid.

¹H NMR (CDCl₃, 400 MHz, ppm): δ 7.81-7.76 (m, 3H), 7.54-7.50 (m, 5H); ¹³C-NMR (CDCl₃, 400 MHz, ppm): δ 147.61, 136.63, 134.37, 133.11, 132.26, 129.95, 129.31, 128.91, 117.61, 115.92, 115.43, 114.76.

### 1.3 1,8(11),15(18),22(25)-Tetraphenyl zincphthalocyanine (ortho-tetraphenyl zincphthalocyanine)

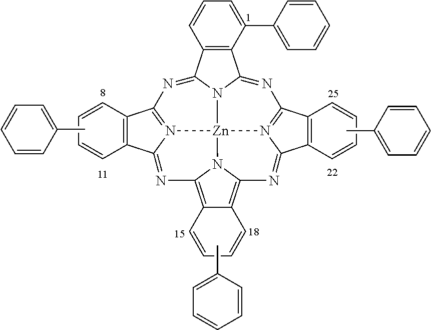

3-Phenylphthalonitrile (10 mmol, 2.04 g), zinc acetate (3.32 mmol, 0.55 g), urea (16.66 mmol, 1 g) and ammonium molybdate (0.20 mmol, 0.04 g) were dissolved in 15 mL of distilled nitrobenzene and heated at 185° C. for 17 h. The reaction mixture was cooled down and diluted with methanol. The solid precipitated out was filtered and washed with methanol and acetonitrile. The solid was air-dried. The solid was again purified by dissolving the crude product in formic acid and precipitating it using methanol. This procedure was repeated twice. The solid was washed very well with water and methanol again and dried under vacuum for 5 hours to give 0.95 g (43.2%) of the title compound.

MALDI-TOF Ms.: 879.89 (DHB matrix). UV-vis (THF): λₘₐₓ=684 nm.

¹H-NMR ((CD₃)₂SO, 400 MHz, ppm): δ 8.64 (d, 4H), 8.26-8.24 (m, 8H), 8.12-8.09 (t, 4H), 8.01 (d, 4H), 7.86-7.84 (m, 12H).

### Example 2

### ortho-Tetranaphthyl zincphthalocyanine

### 2.1 3-Naphthalen-1-yl-phthalonitrile

3-Chlorophthalonitrile (14 mmol, 2.26 g), 1-naphthalene boronic acid (17 mmol, 2.9 g), Pd[P(tBu)₃]₂ (0.1 mmol, 0.051 g), and CsF (28 mmol, 4.22 g) were added to a dry 100 mL two-neck flask in an argon atmosphere and dried under vacuum for few minutes and kept under argon atmosphere. 50 mL of dry dioxane were added to the flask and then stirred at room temperature. To the stirred solution, 2 mL of degassed water was added through a syringe and stirred at 85° C. for 17 hours. After completion of the reaction, the reaction mixture was cooled to room temperature and diluted with dichloromethane and filtered through celite. The filtrate was concentrated and purified by column chromatography using hexane/toluene (3:2) as eluents. 2.5 g (76.1%) of the title compound as colourless solid were obtained.

¹H-NMR (CDCl₃, 400 MHz, ppm): δ 8.01-7.95 (m, 2H), 7.90 (dd, 1H), 7.84-7.79 (m, 2H), 7.61-7.41 (m, 5H); ¹³C-NMR (CDCl₃, 400 MHz, ppm): δ 146.87, 135.84, 134.16, 133.94, 132.64, 131.12, 130.37, 129.01, 127.94, 127.40, 126.76, 125.42, 124.67, 117.25, 116.98, 115.82, 114.81

### 2.2 1,8(11),15(18),22(25)-Tetranaphthyl zincphthalocyanine (ortho-tetranaphthyl zincphthalocyanine)

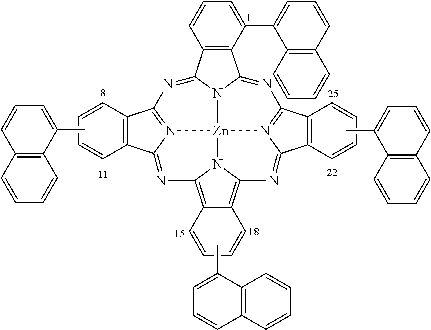

3-Naphthalen-1-yl-phthalonitrile (9.5 mmol, 2.41 g), zinc acetate (3.16 mmol, 0.58 g), urea (16.66 mmol, 1.0 g) and ammonium molybdate (0.20 mmol, 0.04 g) were dissolved in 16 mL of distilled nitrobenzene and heated at 185° C. for 6 hours. The reaction mixture was cooled down and diluted with methanol. The solid precipitated out was filtered and washed with methanol and acetonitrile. The solid obtained was dissolved in formic acid and precipitated it using methanol. This procedure was repeated twice. The solid was washed very well with water and methanol again and dried under vacuum for 15 hours to give 1.42 g (55.3%) of the title compound.

MALDI-TOF Ms.: 1081.03 (DHB matrix); UV-Vis (THF): λₘₐₓ=679.5 nm. ¹H-NMR (d⁸THF, 400 MHz, ppm): δ 8.38 (d, 4H), 8.25-8.22 (m, 4H), 7.97-7.56 (m, 24H), 7.44-7.39 (m, 4H), 7.00-6.89 (m, 4H).

### Example 3

### ortho-Tetraanthracenyl zincphthalocyanine

### 3.1 3-Anthracen-9-yl-phthalonitrile

3-Chlorophthalonitrile (15 mmol, 1.62 g), 9-anthracene boronic acid (18 mmol, 4 g), Pd[P(tBu)₃]₂ (0.14 mmol, 0.072 g), and CsF (30 mmol, 4.53 g) were added to a dry 100 mL two-neck flask in an argon atmosphere and dried under vacuum for few minutes and again kept under argon atmosphere. 30 mL of dry dioxane were then added to the flask and then stirred at room temperature. To the stirred solution, 2 mL of degassed water were added through a syringe. After completion of the addition the reaction mixture was stirred at 85° C. for 17 hours. The reaction mixture was cooled down to room temperature, diluted with dichloromethane and filtered through celite. The filtrate was concentrated and purified by column chromatography using hexane/ethyl acetate (3:1) as eluents (Combiflash automated flash chromatography system). The solid obtained after column chromatography was washed with methanol to give 2.5 g (54.8%) of the title compound as colorless solid.

¹H-NMR (CDCl₃, 400 MHz, ppm): δ 8.63 (s, 1H), 8.10 (d, 2H), 8.01 (dd, 1H), 7.93 (t, 1H), 7.81 (dd, 1H), 7.53-7.49 (m, 2H), 7.46-7.42 (m, 2H), 7.3 (dd, 2H). ¹³C-NMR (CDCl₃, 400 MHz, ppm): δ 145.57, 136.95, 133.12, 131.38, 130.11, 129.77, 129.55, 129.21, 127.27, 125.72, 124.85, 118.54, 117.34, 115.76, 114.37.

### 3.2 1,8(11),15(18),22(25)-Tetraanthracenyl zincphthalocyanine (ortho-tetraanthracenyl zincphthalocyanine)

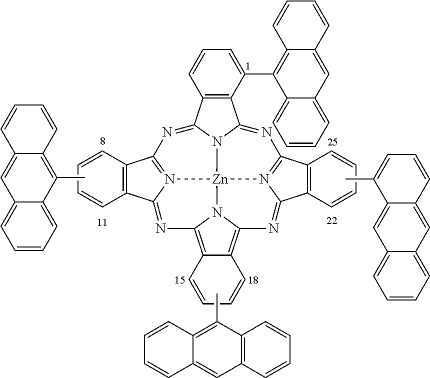

3-Anthracen-9-yl-phthalonitrile (7 mmol, 2.12 g), zinc acetate (2.33 mmol, 0.46 g), urea (12.5 mmol, 0.75 g) and ammonium molybdate (0.15 mmol, 0.03 g) were dissolved in 12 mL of distilled nitrobenzene and heated at 185° C. for 7 hours. The reaction mixture was cooled down and diluted with methanol. The solid precipitated out was filtered and washed with methanol and acetonitrile. The solid was dried under vacuum for 5 hours. (Yield=2.2 g). The solid was purified by the precipitation from formic acid using methanol. Purification using formic acid was repeated twice. The dark green solid was washed with water, acetone and THF. The solid was vacuum dried for 8 hours to give 1.66 g (74.1%) of the title compound.

MALDI-TOF Ms.: 1278.09 (without matrix); UV-Vis (THF): λₘₐₓ=681 nm.

### Example 4

### ortho-tetra(2′,5′-Dichlorophenyl)zincphthalocyanine

### 4.1 3-Bromophthalonitrile

3-Fluorophthalonitrile (25 mmol, 3.65 g) and lithium bromide (6.5 g, 75 mmol) were refluxed at 250° C. in anhydrous NMP for 5 hours. After 5 hours, reaction mixture was cooled down and poured into crushed ice. The solid precipitated out was filtered and washed well with water and allowed to air dry for 15 h and then dried under vacuum for 16 hours to give 2.44 g (47.2%) of the title compound.

¹H NMR (CDCl₃, 400 MHz, ppm): δ 7.95 (d, 1H), 7.77 (d, 1H), 7.59 (t, 1H); ¹³C NMR (CDCl₃, 400 MHz, ppm): δ 137.49, 133.95, 132.27, 127.35, 119.15, 118.36, 114.77, 114.28.

### 4.2 342-(1,4-Dichloro-)phenyl]phthalonitrile

3-Bromophthalonitrile (8 mmol, 1.61 g), 2,5-dichlorophenyl boronic acid (11 mmol, 2.09 g), tris(dibenzylideneacetone)dipalladium(0) (Pd₂(dba)₃) (0.125 mmol, 0.11 g) and Cs₂CO₃ (10 mmol, 3.25 g) were added to a dry 100 mL two-neck flask in an argon atmosphere and dried under vacuum for few minutes and kept under argon atmosphere. 50 mL of dry dioxane were then added to the flask and stirred at room temperature. To the stirred solution, P(tBu)₃ (0.3 mmol, 0.060 g) was added through a syringe. After completion of the addition the reaction mixture was stirred at 90° C. for overnight. The reaction mixture was cooled down to room temperature, diluted with ether and filtered through celite. The filtrate was concentrated and subjected to column chromatography in silica using hexane/ethyl acetate mixture as eluents (4:1). 0.8 g (36.6%) of the title compound as colorless solid were obtained.

¹H-NMR (CDCl₃, 400 MHz, ppm): δ 7.87 (dd, 1H), 7.81 (t, 1H), 7.68 (dd, 1H), 7.49 (d, 1H), 7.43 (dd, 1H), 7.33 (d, 1H); ¹³C-NMR (CDCl₃, 400 MHz, ppm): δ 143.75, 136.82, 134.83, 133.47, 133.30, 133.06, 131.60, 131.42, 131.34, 130.86, 117.12, 116.63, 115.45, 114.27.

### 4.3 1,8(11),15(18),22(25)-Tetra(2′,5′-dichlorophenyl)zincphthalocyanine (ortho-tetra(2′,5′-dichlorophenyl)zincphthalocyanine)

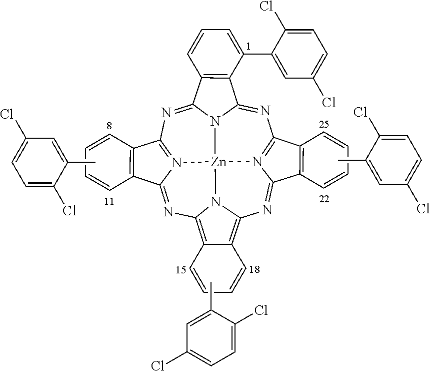

3-[2-(1,4-dichloro-)phenyl]phthalonitrile (3 mmol, 0.816 g), zinc acetate (1 mmol, 0.183 g), urea (8.33 mmol, 0.5 g) and ammonium molybdate (0.05 mmol, 0.01 g) were dissolved in 10 mL of distilled nitrobenzene and heated at 185° C. for 7 hours. The reaction mixture was cooled down and diluted with dichloromethane. The green solution was extracted with dichloromethane and water. The organic phase was dried under magnesium sulphate and concentrated to give green blue liquid. Hexane was added. The blue green solid precipitated out was filtered. The solid obtained was washed thoroughly with hexane and methanol repeatedly. The solid was dried under vacuum for 5 hours to give 0.55 g (63.5%) of the title compound.

MALDI-TOF Ms.: 1155.85 (without matrix); UV-Vis (THF): λₘₐₓ=674 nm.

¹H-NMR (CDCl₃, 400 MHz, ppm): δ 8.64-8.61 (m, 4H), 8.18-8.14 (m, 4H), 8.02-7.95 (m, 8H), 7.88-7.82 (m, 8H).

### Example 5

### meta-Tetraphenyl zincphthalocyanine

### 5.1 4-Phenylphthalonitrile

4-Iodophthalonitrile (6 mmol, 1.5 g), phenyl boronic acid (6 mmol, 0.73 g), Pd₂(dba)₃ (0.075 mmol, 0.068 g) and Cs₂CO₃ (6 mmol, 1.95 g) were added to a dry 100 mL two-neck flask in an argon atmosphere and dried under vacuum for few minutes and kept under argon atmosphere. 10 mL of dry dioxane were added to the flask and stirred at room temperature. To the stirred solution, P(tBu)₃ (0.18 mmol, 0.036 g) was added through a syringe. After completion of the addition the reaction mixture was stirred at 90° C. for 6.5 hours. The reaction mixture was cooled down to room temperature, diluted with ether and filtered through celite. The filtrate was concentrated and purified using column chromatography using hexane:ethyl acetate as eluents (4:1) to give 0.9 g (73.6%) of the title compound as colorless solid.

¹H-NMR (CDCl₃, 400 MHz, ppm): δ 8.01 (d, 1H), 7.94-7.86 (m, 2H), 7.59-7.47 (m, 5H); ¹³C NMR (CDCl₃, 400 MHz, ppm): δ 146.72, 137.17, 134.17, 132.21, 131.63, 130.02, 129.74, 127.42, 116.73, 115.67, 115.62, 114.21.

### 5.2 2,9(10),16(17),23(24)-Tetraphenylzincphthalocyanine(meta-tetraphenyl zincphthalocyanine)

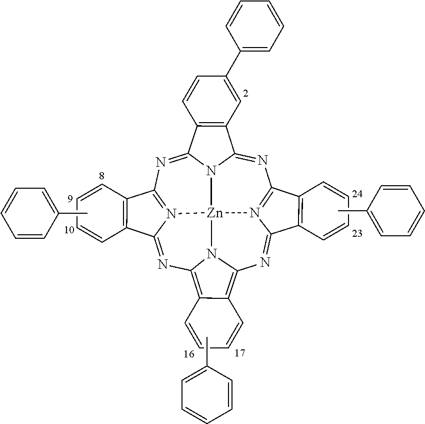

4-Phenylphthalonitrile (2 mmol, 0.408 g), zinc acetate (0.67 mmol, 0.13 g), urea (3.33 mmol, 0.2 g) and ammonium molybdate (0.05 mmol, 0.01 g) were dissolved in 10 mL of nitrobenzene and heated at 185° C. for 6.5 hours and stirred at room temperature for 15 h. The reaction mixture was diluted with acetone and then with acetonitrile. The solid obtained was filtered and the solid was washed well with methanol until the filtrate was colorless (0.4 g). The material was purified by dissolving in formic acid and precipitated out using methanol. This process was repeated three times. Yield after purification was 0.1 g (22.7%).

MALDI-TOF Ms.: 879.65 (without matrix); UV-Vis (THF): λₘₐₓ=683.5 nm.

### Example 6

### ortho-tetrakis[4-(n-butyl)phenyl]zincphthalocyanine

### 6.1 3-(4-Butyl)benzen-1-yl-phthalonitrile

3-Chlorophthalonitrile (15 mmol, 2.43 g), 4-butylphenyl boronic acid (17 mmol, 3.02 g), Pd[P(tBu)₃]₂ (0.1 mmol, 0.051 g), and CsF (30 mmol, 4.53 g) were added to a dry 100 mL two-neck flask in an argon atmosphere and dried under vacuum for few minutes and kept under argon atmosphere. 40 mL of dry dioxane were then added to the flask and stirred at room temperature. To the stirred solution 2 mL of degassed water were added through a syringe and stirred at 85° C. for 7 hours. After completion of the reaction, the reaction mixture was cooled to room temperature and diluted with dichloromethane and filtered through celite. The filtrate was concentrated and purified by column chromatography using hexane/ethylacetate (3:1) as eluents to give 2.5 g (64.1%) of the title compound as colorless liquid.

¹H NMR (CDCl₃, 400 MHz, ppm): δ 7.76-7.74 (m, 3H), 7.47-7.45 (dd, 2H), 7.34-7.32 (dd, 2H), 2.70-2.66 (t, 3H), 1.68-1.61 (m, 2H), 1.44-1.36 (m, 2H), 0.97-0.93 (t, 3H); ¹³C NMR (CDCl₃, 400 MHz, ppm): δ 147.65, 145.11, 134.32, 133.89, 133.03, 131.97, 129.34, 128.78, 117.56, 116.00, 115.62, 114.51, 35.63, 33.60, 22.61, 14.16.

### 6.2 1,8(11),15(18),22(25)-Tetrakis[4-(n-butyl)phenyl]zincphthalocyanine (ortho-tetrakis[4-(n-butyl)phenyl]zincphthalocyanine

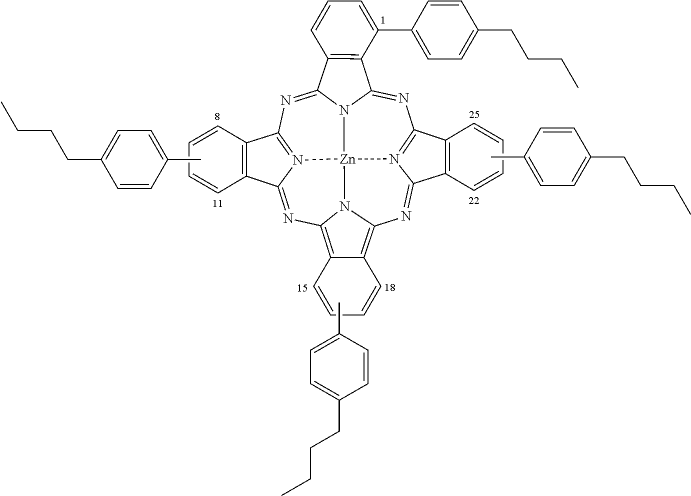

3-(4-Butyl)benzen-1-yl-phthalonitrile (6 mmol, 1.56 g), zinc acetate (2 mmol, 0.36 g), urea (12.48 mmol, 0.75 g) and ammonium molybdate (0.10 mmol, 0.02 g) were dissolved in 10 mL of distilled nitrobenzene and heated at 185° C. for 17 hours. The reaction mixture was cooled down and diluted with methanol. The solid precipitated out was filtered and washed with methanol and acetonitrile. The solid was again purified by dissolving the crude product in formic acid and precipitating it using methanol. This procedure was repeated twice. The bluish green solid was washed very well with water, methanol and ethanol and dried under vacuum for 6 hours to give 1.22 g (73.9%) of the title compound.

LC/Ms analysis showed a mass of 1106.3. UV-Vis (THF): λₘₐₓ=at 686.5 nm.

### Example 7

### ortho-Tetrakis[4-(tert-butyl)phenyl]zincphthalocyanine

### 7.1 3-(4-tert-Butyl)benzen-1-yl-phthalonitrile

3-Chlorophthalonitrile (10 mmol, 1.62 g), 4-tert-butyl phenyl boronic acid (12 mmol, 2.13 g), Pd[P(tBu)₃]₂ (0.07 mmol, 0.036 g), and CsF (20 mmol, 3.02 g) were added to a dry 100 mL two-neck flask in an argon atmosphere and dried under vacuum for few minutes and kept under argon atmosphere. 20 mL of dry dioxane were added to the flask and then stirred at room temperature. To the stirred solution, 2 mL of degassed water were added through a syringe and stirred at 85° C. for 17 hours. After completion of the reaction, the reaction mixture was cooled to room temperature and diluted with dichloromethane and filtered through celite. The filtrate was concentrated and purified by column chromatography using hexane/toluene (3:1) as eluents to give 2.0 g (76.9%) of the title compound as colorless solid.

¹H NMR (CDCl₃, 400 MHz, ppm): δ 7.78-7.72 (m, 3H), 7.55-7.48 (d d, 4H), 1.37 (s, 9H); ¹³C NMR (CDCl₃, 400 MHz, ppm): δ 153.25, 147.55, 134.35, 133.65, 133.05, 131.99, 128.62, 126.31, 117.61, 116.02, 115.66, 114.49, 35.05, 31.45.

### 7.2 1,8(11),15(18),22(25)-Tetrakis[4-(tert-butyl)phenyl]zincphthalocyanine (ortho-tetrakis[4-(tert-butyl)phenyl]zincphthalocyanine)

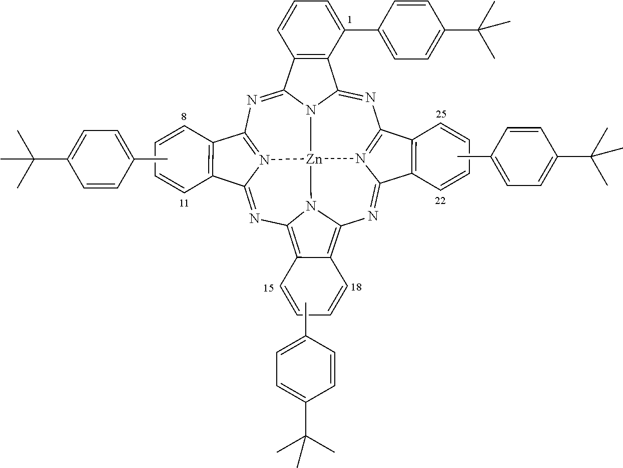

3-(4-tert-Butyl)benzen-1-yl-phthalonitrile (6 mmol, 1.56 g), zinc acetate (2 mmol, 0.36 g), urea (12.48 mmol, 0.75 g) and ammonium molybdate (0.10 mmol, 0.02 g) were dissolved in 10 mL of distilled nitrobenzene and heated at 185° C. for 8 hours. The reaction mixture was cooled down and diluted with methanol. The solid precipitated out was filtered and washed with methanol and acetonitrile. The solid was again purified by dissolving the crude product in formic acid and precipitating it using methanol. This procedure was repeated twice. The dark blue solid was washed very well with water, methanol and ethanol and dried under vacuum for 6 hours to give 1.2 g (72.7%) of the title compound.

LC/Ms analysis showed a mass of 1105.3; UV-Vis (THF): λₘₐₓ=686 nm.

### Example 8

### ortho-Tetrathienyl zincphthalocyanine

### 8.1 3-Thiophen-2-yl-phthalonitrile

3-Chlorophthalonitrile (10 mmol, 1.62 g), 2-thienyl boronic acid (13 mmol, 1.66 g), Pd[P(tBu)₃]₂ (0.07 mmol, 0.036 g), and CsF (20 mmol, 3.02 g) were added to a dry 100 mL two-neck flask in an argon atmosphere and dried under vacuum for few minutes and kept under argon atmosphere. 20 mL of dry dioxane were added to the flask and stirred at room temperature. To the stirred solution, 2 mL of degassed water was added through a syringe and stirred at 85° C. for 17 hours. The reaction mixture was cooled down to room temperature, diluted with dichloromethane and filtered through celite. The filtrate was concentrated and purified by column chromatography using 1:1 toluene/hexane as eluents. The title compound was the first eluate from the column. 1.5 g (71.4%) of the title compound as colorless solid were obtained.

¹H NMR (CDCl₃, 400 MHz, ppm): δ 7.87-7.84 (m, 1H), 7.71-7.70 (m, 3H), 7.51 (d, 1H), 7.19 (t, 1H); ¹³C-NMR (CDCl₃, 400 MHz, ppm): δ 139.75, 137.57, 133.77, 133.24, 132.03, 129.17, 129.09, 128.89, 118.24, 115.77, 113.05

### 8.2 1,8(11),15(18),22(25)-Tetrathien-2-yl zincphthalocyanine (ortho-tetrathien-2-yl zincphthalocyanine)

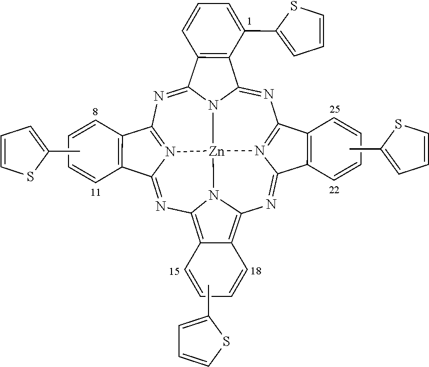

3-Thiophen-2-yl-phthalonitrile (5 mmol, 1.05 g), zinc acetate (1.66 mmol, 0.28 g), urea (8.33 mmol, 0.5 g) and ammonium molybdate (0.1 mmol, 0.02 g) were dissolved in 10 mL of distilled nitrobenzene and heated at 185° C. for 7 hours. The reaction mixture was cooled down and diluted with methanol. The solid precipitated out was filtered and washed with methanol and acetonitrile. The solid obtained was dissolved in formic acid and precipitated it using methanol. This procedure was repeated twice. The solid was washed very well with water and methanol and dried under vacuum for 8 hours to give 0.63 g (55.8%) of the title compound.

MALDI-TOF Ms.: 902.6 (without matrix); UV-Vis (THF): λₘₐₓ=692.5 nm.

¹H-NMR ((CD₃)₂SO, 400 MHz, ppm): δ 9.00-8.97 (dd, 4H), 8.65 (d, 4H), 8.18-8.11 (m, 8H), 8.05 (dd, 4H), 7.71-7.69 (m, 4H).

### Example 9

### ortho-tetra(5″-hexyl-2′,2″-bithiophene)zincphthalocyanine

### 9.1 3-(5′-Hexyl-[2,2′]bithiophenyl-5-yl)-phthalonitrile

3-Chlorophthalonitrile (10 mmol, 1.62 g), 5′-hexyl-2,2′-bithiophene-5-boronic acid pinacol ester (10 mmol, 3.76 g) and Pd[P(tBu)₃] (0.07 mmol, 0.036 g) were added to a dry 100 mL two-neck flask in an argon atmosphere and dried under vacuum for few minutes and kept under argon atmosphere. 20 mL of dry dioxane were added to the flask and stirred at room temperature. To the stirred solution 1.2 mL of degassed NaOH (5N solution) was added through a syringe. After completion of the addition the reaction mixture was stirred at 70° C. for 17 hours. The reaction mixture was diluted with dichloromethane and filtered through celite. The filtrate was concentrated and subjected to column chromatography using toluene/hexane mixture as eluent (1:3). The yellow solid obtained was washed with methanol and dried under vacuum for 3 hours to give 1.8 g (47.9%) of the title compound as yellowish solid.

¹H-NMR (CDCl₃, 400 MHz, ppm): δ 7.85-7.82 (m, 1H), 7.69-7.65 (m, 3H), 7.14 (d, 1H), 7.07 (d, 1H), 6.71 (d, 1H), 2.806 (t, 2H), 1.72-1.64 (m, 2H), 1.4-1.29 (m, 6H), 0.89 (t, 3H).

### 9.2 1,8(11),15(18),22(25)-Tetra(5″-hexyl-2′,2″-bithiophene)zincphthalocyanine (ortho-tetra(5″-hexyl-2′,2″-bithiophene)zincphthalocyanine)

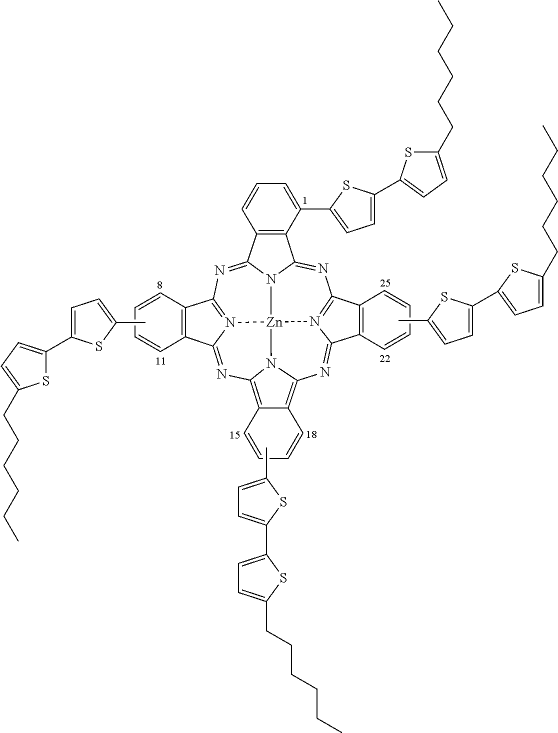

3-(5′-Hexyl-[2,2′]bithiophenyl-5-yl)-phthalonitrile (3 mmol, 1.12 g), zinc acetate (1.0 mmol, 0.18 g), urea (8.33 mmol, 0.5 g) and ammonium molybdate (0.1 mmol, 0.02 g) were dissolved in 8 mL of distilled nitrobenzene and heated at 185° C. for 6 hours. The reaction mixture was cooled down and diluted with methanol. The solid precipitated was filtered off and washed thoroughly with methanol. The greenish solid obtained was dissolved in formic acid and precipitated using methanol. This process was repeated three times. The solid was washed thoroughly with water and methanol, dried to give 0.7 g (59.8%) of the title compound. The compound was subjected to column chromatography in silica using hexane/ethyl acetate as eluents (3:1). The solid obtained after column chromatography was again washed with methanol and dried under vacuum for 6 hours to give 0.49 g (41.5%) of the title compound as dark greenish solid.

MALDI-TOF Ms.: 1568.62 (DHB matrix); UV-Vis (THF): λₘₐₓ=719.5 nm.

### Example 10

### Meta-Tetrafluoro-meta-tetraphenylzincphthalocyanine

### 10.1 4-Chloro-5-fluoro-phthalodinitrile

A mixture of 250 mL of toluene, 21.8 g (375 mmol) potassium fluoride, 14.8 g (75 mmol) of 4,5-dichlorophthalodinitrile and 3.69 g of N,N′-dimethylimidazolidino-tetramethylguandidium chloride (J. Fluoride Chemistry 2004, 125, 1031-1038) were heated to 90° C. for 16 hours. Then the mixture was diluted with toluene, filtered and concentrated. The product was isolated by chromatography on silica using petrolether, petrolether-toluene mixtures. 7.5 g (55%) of a white solid were obtained. Rf (toluene acetone 100:1)=0.39

### 10.2 4-Fluoro-5-phenyl-phthalodinitrile

A mixture of 100 mL of dioxane, 4.0 g (22.2 mmol) of 4-Chloro-5-fluoro-phthalodinitrile, 2.94 g (24.1 mmol) of phenylboronic acid, 14.58 g (44.7 mmol) of Cs₂CO₃, 0.51 g (0.56 mmol) of tris(dibenzylideneacetone)dipalladium(0) and 0.135 g of tritertbutylphosphine were heated to 90° C. for 10 hours. The reaction mixture was cooled to room temperature, diluted with dichloromethane and filtered. The solvents were evaporated and 5.0 g of the crude product were recrystallized from 50 mL of refluxing heptane to which was added toluene until everything dissolved (ca. 20 ml). 2.34 g (47%) of a white product were obtained. According to ¹H-NMR the purity of the product was about 95%.

R_{f}(toluene acetone 100:1)=0.37

### 10.3 meta-Tetrafluoro-meta-tetraphenylzincphthalocyanine

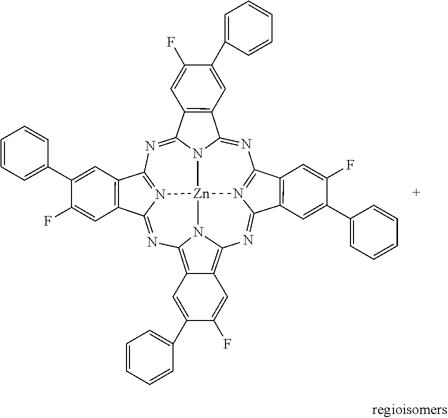

Through a mixture of 50 mL nitrobenzene, 2.22 g (10 mmol) of 4-fluoro-5-phenyl-phthalodinitrile, 0.482 g (2.63 mmol) of zinc acetate and 37 mg (0.26 mmol) of MoO₃ was bubbled ammonia. The mixture was heated to 220° C. within 100 minutes and kept at this temperature for 6 hours. The reaction mixture was cooled and the product was precipitated with petroleum ether, filtered and washed with petroleum ether. The product was purified by column chromatography.

R_{f} (toluene ethanol 10:1)=0.9

The compounds of the formula Ib-oPclisted in the following table 1 were prepared analogously, the substituent R^{a2} being attached in position 8 or 11, the substituent R^{a3} being attached in position 15 or 18 and the substituent R^{a4} being attached in position 22 or 25.

TABLE 1
(Ib-oPc)

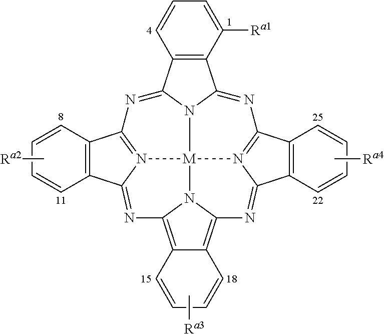

| Example | M | R^{a1} | R^{a2} | R^{a3} | R^{a4} |
|---|---|---|---|---|---|
| 11 | Zn | phenoxy | phenoxy | phenoxy | phenoxy |
| 12 | Zn | 4-trifluoro- | 4-trifluoro- | 4-trifluoro- | 4-trifluoro- |
| | | methyl- | methyl- | methyl- | methyl- |
| | | phenoxy | phenoxy | phenoxy | phenoxy |
| 13 | Zn | 2- | 2- | 2- | 2- |
| | | benzo[b]- | benzo[b]- | benzo[b]- | benzo[b]- |
| | | thienyl | thienyl | thienyl | thienyl |
| 14 | Zn | thiophene- | thiophene- | thiophene- | thiophene- |
| | | 3-yl | 3-yl | 3-yl | 3-yl |
| 15 | Cu | phenoxy | phenoxy | phenoxy | phenoxy |
| 16 | Cu | thiophene- | thiophene- | thiophene- | thiophene- |
| | | 2-yl | 2-yl | 2-yl | 2-yl |
| 17 | Zn | 3-CN—C₆H₄ | 3-CN—C₆H₄ | 3-CN—C₆H₄ | 3-CN—C₆H₄ |
| 18 | Zn | furan-2-yl | furan-2-yl | furan-2-yl | furan-2-yl |
| 19 | Zn | 5-methyl- | 5-methyl- | 5-methyl- | 5-methyl- |
| | | thiophene- | thiophene- | thiophene- | thiophene- |
| | | 2-yl | 2-yl | 2-yl | 2-yl |
| 20 | Zn | 5-methyl- | 5-methyl- | 5-methyl- | 5-methyl- |
| | | furan-2-yl | furan-2-yl | furan-2-yl | furan-2-yl |

### Example 21

### 2,9(10),16(17),23(24)-Tetrathien-2-yl zinc phthalocyanine (meta-tetrathiophen-2-yl zincphthalocyanine)

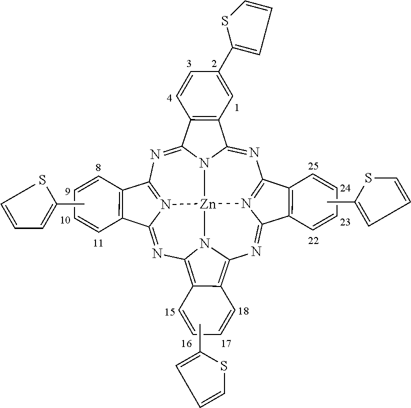

The title compound was prepared in an analogous manner as described above.

### Example 22

### 1,8(11),15(18),22(25)-Tetrakis(2,6-diphenylphenoxy)-phthalocyanine

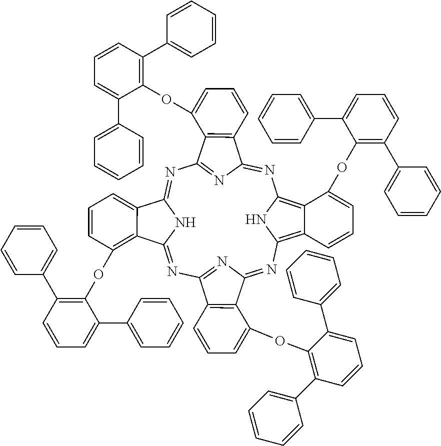

The title compound was prepared as described in WO 2007/104685.

### Example 23

### 1,8(11),15(18),22(25)-Tetrathien-2-yl phthalocyanine (ortho-tetrathien-2-yl phthalocyanine)

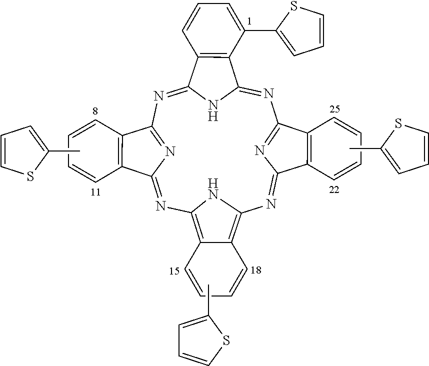

Thiophene 2-yl-phthalonitrile (5 mmol, 1.05 g) was dried under vacuum for 20 minutes in a reaction flask. After drying anhydrous 1-hexanol (15 mL) and 1,8-diazabicyclo[5.4.0]undec-7-ene (0.65 mmol, 0.1 mL) were added to the reaction flask and refluxed for 24 hours. The reaction mixture was cooled down and diluted with diethyl ether. The solid precipitated was filtered off and washed well with methanol and acetone. The dark green solid obtained was dried under vacuum at 60° C. for 6 hours to yield a dark green solid. Yield=0.67 G (63.8%).

UV-vis (THF): λₘₐₓ=729 nm.

### Example 24

### 1,8(11),15(18),22(25)-Tetrafuran-2-yl phthalocyanine (ortho-tetrafuran-2-yl phthalocyanine)

The title compound was prepared in an analogous manner as described above for example 23.

### II. Performance Properties when Used in Devices

### II.1 Performance Properties for Compounds of Formula Ib

### Materials:

ortho-Tetraphenyl zincphthalocyanine from example 1, purified in a zone gradient sublimation apparatus; the pressure was below 1×10⁻⁵ mbar throughout the sublimation process and the sublimation temperature was 370° C., Yield 50%. ortho-Tetranaphthyl zincphthalocyanine from example 2, purified in a zone gradient sublimation apparatus; the pressure was below 1×10⁻⁵ mbar throughout the sublimation process and the sublimation temperature was 440° C., Yield 18%.

C60, obtained from Creaphys, purified twice by sublimation, used as received.

Bphen (4,7-diphenyl-1,10-phenanthroline), obtained form Alfa Aesar, used as received.

### Substrate Preparation

An indium tin oxide layer (ITO) was sputtered on a glass substrate. The thickness of the ITO layer was 140 nm, the resistivity was 200 μΩcm and the RMS (roughness mean square) was <5 nm. The substrate was UV ozoned for 20 minutes prior to organic deposition.

Two types of cells (bilayer and bulk heterojunction (BHJ)) were fabricated in high vacuum system (pressure <10⁻⁶ mbar).

Bilayer cell (ITO/substituted phthalocyanine according to the present invention/C60/Bphen/Ag): The bilayer cell was built with substituted phthalocyanine and C60 evaporated in turns on ITO substrate. The deposition rate was 2 nm/sec for both layer. The evaporation temperatures of substituted phthalocyanines are listed in the Table 2 below:

TABLE 2

| | Evaporation |
|---|---|
| Substituted Phthalocyanine | Temperature [° C.] |
| ortho-Tetraphenyl zincphthalocyanine | 380° C. |
| (from example 1) | |
| ortho-Tetranaphthyl zincphthalocyanine | 440° C. |
| (from example 2) | |
| ortho-Tetra(2′,5′-dichlorophenyl) | 360° C. |
| zincphthalocyanine (from example 4) | |
| compound from example 7 | 400° C. |
| compound from example 8 | 375° C. |
| compound from example 11 | 400° C. |
| compound from example 13 | 430° C. |
| compound from example 14 | 390° C. |
| compound from example 15 | 390° C. |
| compound from example 16 | 290° C. |
| compound from example 21 | 380° C. |

C60 was evaporated at 400° C. Bphen evaporation was followed on top of the mixed layer. Finally 100 nm of Ag was evaporated for the top contact. The device had an area of 0.031 cm².

The bulk heterojunction cell (ITO/substituted phthalocyanine according to the present invention:C60(1:1 by weight)/C60/Bphen/Ag) structure was built as follows: Substituted phthalocyanine and C60 were coevaporated on ITO at same rate (0.1 nm/sec) to have 1:1 weight ratio of substituted phthalocyanine and C60 mixed layer. Bphen and Ag layer deposition were the same as described above in bilayer cell.

### Measurement

AM 1.5 simulator from Solar light Co. inc using a xenon lamp (Model 16S-150 V3) was used. The UV region under 415 nm was filtered and current/voltage measurement was performed under ambient condition. The solar simulator intensity is calibrated with a monocrystalline FZ silicon solar cell (Fraunhofer ISE). The mismatch factor was calculated to be close to 1.0.

### Device Result

The phthalocyanines according to the present invention which were used in devices were measured with a light intensity of 100 mW/cm².

The performance data of the bilayer solar cells which comprised the phthalocyanines according to the invention as donors is shown in the following Table 3.

TABLE 3

| | VOC | JSC | | |
|---|---|---|---|---|
| Substituted Phthalocyanine | (mV) | (mA/cm²) | FF | η (%) |
| ortho-tetraphenyl zincphthalo- | 680 | −5.6 | 68 | 2.4 |
| cyanine (from ex. 1) | | | | |
| ortho-tetranaphthyl zinc- | 760 | −4.26 | 59 | 1.9 |
| phthalocyanine (from ex. 2) | | | | |
| ortho-tetra(2′,5′-dichloro- | 700 | −2.5 | 56 | 1.0 |
| phenyl) zincphthalocyanine | | | | |
| (from ex. 4) | | | | |
| compound from example 7 | 700 | 5.0 | 50 | 1.8 |
| compound from example 8 | 650 | 6.2 | 64 | 2.6 |
| compound from example 11 | 610 | 4.9 | 64 | 1.9 |
| compound from example 13 | 700 | 4.1 | 46 | 1.3 |
| compound from example 14 | 560 | 5 | 61 | 1.7 |
| compound from example 15 | 620 | 5.1 | 58 | 1.9 |
| compound from example 16 | 550 | 3.9 | 50 | 1.1 |

The performance data of the bulk heterojunction solar cells which comprised the phthalocyanines according to the invention as donors is shown in the following Table 4.

TABLE 4

| | V_{OC} | J_{SC} | | |
|---|---|---|---|---|
| Substituted Phthalocyanine | (mV | (mA/cm²) | FF | η (%) |
| ortho-phenyl zincphthalocyanine | 680 | −5.6 | 68 | 2.4 |
| (from ex. 1) | | | | |
| compound from example 7 | 440 | 5.2 | 52 | 1.2 |
| compound from example 8 | 630 | 13.8 | 61 | 5.2 |
| compound from example 11 | 470 | 7.8 | 56 | 2.0 |
| compound from example 13 | 410 | 4.5 | 52 | 1.0 |
| compound from example 15 | 460 | 8.3 | 41 | 1.6 |
| compound from example 16 | 470 | 4.7 | 46 | 1.0 |
| compound from example 21 | 275 | 6.4 | 56 | 1.0 |

### II.2 Device Result for Compounds of the Formula Ia

A bilayer device ITO/PEDOT/compound of example 22/PTCBI/BCP/Ag was prepared and the following results were obtained:

### Voc=740 mV

Isc=1.233 mA/cm²

### FF=39.3

Efficiency η=0.359%

1. An organic solar cell, comprising:
at least one photoactive region comprising an organic donor material contacting an organic acceptor material and forming a donor-acceptor heterojunction, wherein the at least one photoactive region comprises at least one compound selected from the group consisting of a compound of formula Ia and a compound of formula Ib 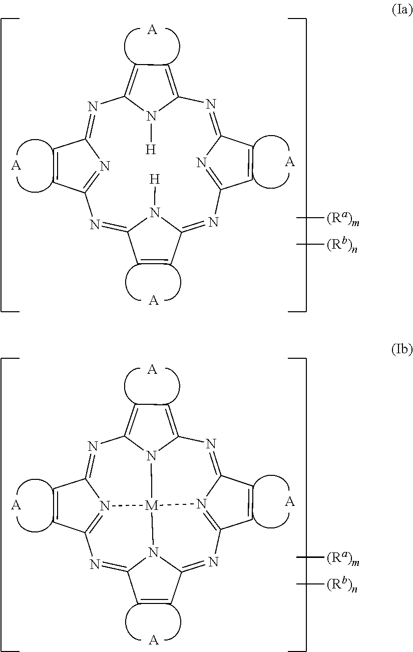
wherein
M is a divalent metal, a divalent metal atom comprising group, or a divalent metalloid group;
A at each occurrence, is independently of each other a fused arene ring selected from the group consisting of a benzene ring, naphthalene ring, anthracene and phenanthrene ring;
R^{a} at each occurrence, is independently an aryl, an aryloxy, an arylthio, a monoarylamino, a diarylamino, a hetaryl, a hetaryloxy, an oligo(het)aryl, or an oligo(het)aryloxy, wherein each aryl, aryloxy, arylthio, monoarylamino, diarylamino, hetaryl, hetaryloxy, oligo(het)aryl, and oligo(het)aryloxy is optionally unsubstituted or optionally comprises at least one substituent R^{aa} independently selected from the group consisting of a cyano, a hydroxyl, a nitro, a carboxyl, a halogen, an alkyl, a haloalkyl, a cycloalkyl, a halocycloalkyl, an alkoxy, a haloalkoxy, an alkylsulfanyl, a haloalkylsulfanyl, an amino, a monoalkylamino, a dialkylamino, a NH(aryl), and a N(aryl)₂;
R^{b} at each occurrence, is independently a cyano, a hydroxyl, a nitro, a carboxyl, a carboxylate, SO₃H, a sulfonate, a halogen, an alkyl, a haloalkyl, a cycloalkyl, a halocycloalkyl, an alkoxy, a haloalkoxy, an alkylsulfanyl, a haloalkylsulfanyl, an amino, a monoalkylamino, or a dialkylamino;
m is an integer from 1 to 16; and
n is an integer from 0 to 23.

2. The cell of claim 1, wherein M in formula Ib is Zn(II), Cu(II), Al(III)F, Al(III)Cl, In(III)F, or In(III)Cl.

3. The cell of claim 1, wherein in the formula Ia and Ib, all rings A are a fused benzene ring.

4. The cell of claim 1, wherein in the formula Ia and Ib, R^{a}, at each occurrence, is a phenyl, a phenyloxy, a phenylthio, a naphthyl, a naphthyloxy, a naphthylthio, an anthracenyl, an anthracenyloxy, an anthracenylthio, an oligothiophenyl, or a hetaryl,
wherein the hetaryl comprises 1, 2, or 3 heteroatoms selected from the group consisting of O, N, Se, and S as ring members, and
wherein the phenyl, the phenyloxy, the phenylthio, the naphthyl, the naphthyloxy, the naphthylthio, the anthracenyl, the antracenyloxy, the anthracenylthio, the oligothiophenyl, and the hetaryl are each unsubstituted or substituted by 1, 2, 3, or 4 substituents R^{aa}.

5. The cell of claim 4, wherein in the formulae Ia and Ib, R^{a}, at each occurrence, is a phenyl, a naphthyl, an anthracenyl, a phenyloxy, a phenylthio, a naphthyloxy, a naphthylthio, an oligothiophenyl, or a 5-membered sulphur comprising hetaryl which optionally comprises additionally 1 or 2 nitrogen atoms as ring members and optionally comprises 1 or 2 fused-on arene rings, and
wherein the phenyl, the phenyloxy, the phenylthio, the naphthyl, the naphthyloxy, the naphthylthio, the anthracenyl, the oligothiophenyl, and the sulphur comprising hetaryl are unsubstituted or substituted by 1 or 2 substituents R^{aa} selected from the group consisting of halogen, a C₁-C₁₀-alkyl, and a C₁-C₁₀-haloalkyl.

6. The cell of claim 5, wherein in the formula Ia and Ib, R^{a}, at each occurrence, is a sulphur comprising hetaryl selected from the group consisting of 2-thienyl, 3-thienyl, thiazol-2-yl, thiazol-5-yl, [1,3,4]thiadiazol-2-yl, and benzo[b]thiophen-2-yl.

7. The cell of claim 6, wherein in the formula Ia and Ib, R^{a}, at each occurrence, is 2 thienyl or 3-thienyl.

8. The cell of claim 1, wherein in the formula Ia and Ib, m is 4 or 8.

9. The cell of claim 1, wherein in the formula Ia and Ib, R^{b}, at each occurrence is halogen.

10. The cell of claim 1, further comprising at least one compound selected from the group consisting of a compound of a formula Ia-oPc and a compound of a formula Ib-oPc, 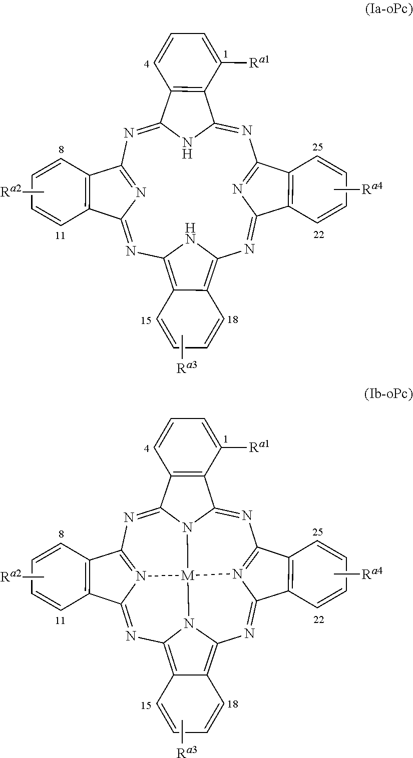
where wherein
M is a divalent metal, a divalent metal atom comprising group or a divalent metalloid group; and
R^{a1}, R^{a2}, R^{a3} and R^{a4} each have one of the meanings given for R^{a};
wherein the substituent R^{a2} is attached in position 8 or 11, the substituent R^{a3} is attached in position 15 or 18 and the substituent R^{a4} is attached in position 22 or 25.

11. The cell of claim 10,
wherein
M is Zn(II); and
R^{a1}, R^{a2}, R^{a3} and R^{a4} are each independently a phenyl, a phenoxy, a phenylthio, a naphthyl, a naphthyloxy, a naphthylthio, an oligothiophenyl, or a 5-membered sulphur comprising hetaryl which optionally comprises an additional 1 or 2 nitrogen atoms as ring members and optionally comprises 1 or 2 fused-on arene rings, and wherein the phenyl, the phenoxy, the phenylthio, the naphthyl, the naphthyloxy, the naphthylthio, and the 5-membered sulphur comprising hetaryl are unsubstituted or substituted by 1 or 2 substituents R^{aa} selected from the group consisting of a halogen, a C₁-C₁₀-alkyl, and a C₁-C₁₀-haloalkyl.

12. The cell of claim 1, wherein at least one compound selected from the group of a compound of formula Ia and a compound of formula Ib is employed in combination with at least one further different semiconductor material.

13. The cell of claim 12, wherein the further semiconductor material comprises at least one selected from the group consisting of a fullerene and a fullerene compound.

14. The cell of claim 12, wherein the further semiconductor material is C60 or [6,6]-phenyl-C61-butyric acid methyl ester.

15. The cell of claim 12, wherein the further semiconductor material comprises at least one rylene.

16. The cell of claim 1, wherein the cell is in the form of a single cell, a tandem cell, or a multijunction solar cell.

17. The cell of claim 16 comprising at least one donor-acceptor heterojunction in the form of a flat heterojunction.

18. The cell of claim 16, comprising at least one donor-acceptor heterojunction in the form of a bulk heterojunction.

19. A compound of a formulae Ia-F or Ib-F 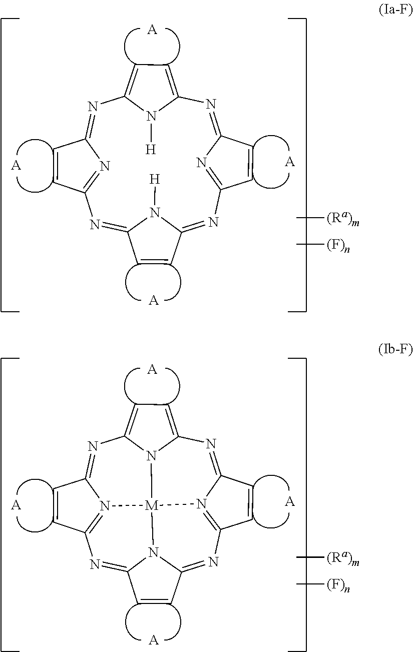
wherein
M is a divalent metal, a divalent metal atom comprising group, or a divalent metalloid group;
A at each occurrence, is a fused arene ring selected from the group consisting of a benzene ring, a naphthalene ring, an anthracene ring, and a phenanthrene ring;
R^{a} at each occurrence, is independently an aryl, an aryloxy, an arylthio, a monoarylamino, a diarylamino, a hetaryl hetaryloxy, an oligo(het)aryl, or an oligo(het)aryloxy, wherein each aryl, aryloxy, arylthio, monoarylamino, diarylamino, hetaryl, hetaryloxy, oligo(het)aryl, or oligo(het)aryloxy is optionally unsubstituted or optionally comprises at least one substituent R^{aa} independently selected from the group consisting of a cyano, a hydroxyl, a nitro, a carboxyl, a halogen, an alkyl, a cycloalkyl, a haloalkyl, a halocycloalkyl, an alkoxy, a haloalkoxy, an alkylsulfanyl, a haloalkylsulfanyl, an amino, a monoalkylamino, a dialkylamino, a NH(aryl), and a N(aryl)₂;
m is an integer from 1 to 15; and
n is an integer from 1 to 23.

20. The compound of claim 19, wherein each ring A comprises one or two substituents R^{a} and one or two substituents F.

21. The compound of claim 19, wherein all rings A are a fused benzene ring and R^{a} is selected from the group consisting of a phenyl, a phenyloxy, a phenylthio, a naphthyl, a naphthyloxy, a naphthylthio, an oligothiophenyl, and a hetaryl,
wherein the hetaryl comprises 1, 2, or 3 heteroatoms selected from the group consisting of O, N, Se, and S as ring members and wherein the phenyl, the phenyloxy, the phenylthio, the naphthyl, the naphthyloxy, the naphthylthio, the oligothiophenyl, and the hetaryl are each unsubstituted or substituted by 1, 2, 3 or 4 substituents R^{aa}.

22. A process for preparing a compound of a formula Ib-F 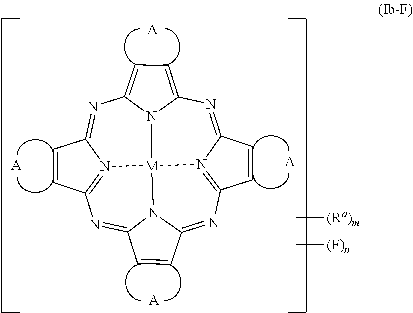
wherein
M is a divalent metal, a divalent metal atom comprising group or a divalent metalloid group,
A at each occurrence, is a fused arene ring selected from the group consisting of a benzene ring, a naphthalene ring, an anthracene ring, and a phenanthrene ring,
R^{a} at each occurrence, is independently an aryl, an aryloxy, an arylthio, a monoarylamino, a diarylamino, a hetaryl hetaryloxy, an oligo(het)aryl, or an oligo(het)aryloxy, wherein each aryl, aryloxy, arylthio, monoarylamino, diarylamino, hetaryl, hetaryloxy, oligo(het)aryl, or oligo(het)aryloxy is optionally unsubstituted or optionally comprises at least one substituent R^{aa} independently selected from the group consisting of a cyano, a hydroxyl, a nitro, a carboxyl, a halogen, an alkyl, a cycloalkyl, a haloalkyl, a halocycloalkyl, an alkoxy, a haloalkoxy, an alkylsulfanyl, a haloalkylsulfanyl, an amino, a monoalkylamino, a dialkylamino, a NH(aryl), and a N(aryl)₂;
m is an integer from 1 to 15, and
n is an integer from 1 to 23,
the process comprising:
a) reacting an educt composition at an elevated temperature with a compound of a metal M,
wherein the educt composition comprises at least one compound selected from the group consisting of a compound of formula IIa, IIb, IIc, and IId 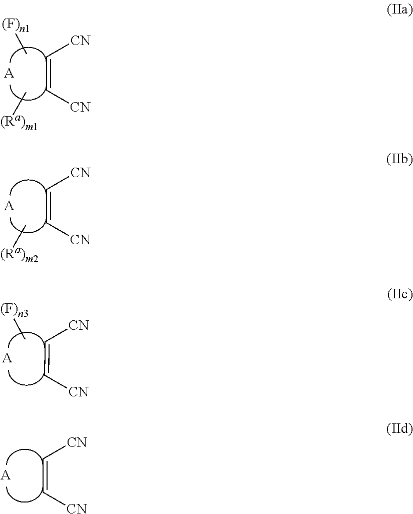
wherein
the groups A are, independently of each other, a fused arene ring selected from the group consisting of a benzene ring, a naphthalene ring, an anthracene ring, and a phenanthrene ring,
m₁ is an integer from 1 to 4,
m₂ is an integer from 1 to 4,
n₁ is an integer from 1 to 7
n₃ is an integer from 0 to 8,
with the proviso that the sum of all indices m₁ and all indices m₂ is not more than 15,
with the proviso that the sum of all indices n₁ and all indices n₂ is not more than 23,
with the proviso that the educt composition comprises at least one compound of the formula IIa or that the educt composition comprises at least one compound of the formula Jib and at least one compound of the formula IIc.
